(19) United States
(12) Patent Application Publication
(10) Pub. No.: US 2026/0164889 A1
(43) Pub. Date: Jun. 11, 2026

(54) DISPLAY DEVICE

(71) Applicant: LG Display Co., Ltd., Seoul (KR)

(72) Inventors: Taehyun KIM, Uijeongbu-si (KR); SungJoon MIN, Goyang-si (KR); Yeonjun OH, Incheon (KR); Dojoong KIM, Seoul (KR); JunHyuk SONG, Seoul (KR)

(73) Assignee: LG Display Co., Ltd., Seoul (KR)

(21) Appl. No.: 19/371,753

(22) Filed: Oct. 28, 2025

(30) Foreign Application Priority Data
Dec. 10, 2024 (KR) 10-2024-0182621

(51) Int. Cl. H10H 29/49

(52) U.S. Cl. CPC H10H 29/49

(57) ABSTRACT

A display device in one or more examples includes: a substrate; a plurality of subpixels disposed on a plurality of pixel plate patterns and each including a circuit; a plurality of lines disposed on the plurality of pixel plate patterns and connected to the circuits; and a plurality of bypass lines disposed on the plurality of pixel plate patterns and the plurality of bypass plate patterns. Some of the plurality of lines on some of the plurality of pixel plate patterns receive signals from corresponding bypass lines of the plurality of bypass lines on some of the plurality of bypass plate patterns. Therefore, the plurality of bypass lines and the plurality of bypass plate patterns may be used to transmit the signal to the normal subpixel on the pixel plate pattern while inhibiting a signal from being applied to a defective subpixel of some pixel plate patterns.

### CROSS-REFERENCE TO RELATED APPLICATIONS

This application claims the benefit of and priority to Korean Patent Application No. 10-2024-0182621 filed on Dec. 10, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, an extendable, stretchable display device.

### 2. Description of Related Art

As display devices used for a monitor of a computer, a TV set, a mobile phone, and the like, there are an organic light-emitting display (OLED) configured to autonomously emit a light, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, display devices have been made by forming display parts, lines, and the like on substrates made of flexible plastic materials and having flexibility. The display devices are manufactured to be stretchable in particular directions and variously changeable in shapes, and thus attract attention as next-generation display devices.

The description of related art should not be considered prior art merely because it is mentioned in or associated with this section. The description of related art includes information that describes one or more aspects of the subject technology, and the description in this section does not limit the scope of the invention.

### SUMMARY

An aspect to be achieved by the present disclosure is to provide a stretchable display device capable of being transformed into various shapes.

Another aspect to be achieved by the present disclosure is to provide a stretchable display device capable of minimizing a bright spot defect by blocking a path through which a signal is applied to a defective subpixel.

Still another aspect to be achieved by the present disclosure is to provide a stretchable display device capable of minimizing a bright spot defect of a defective subpixel by forming a separate bypass signal path separated from the defective subpixel.

Yet another aspect to be achieved by the present disclosure is to provide a stretchable display device capable of transmitting a signal to the remaining normal subpixel by using a bypass line in case that some connection lines are removed because of a defective subpixel.

Still yet another aspect to be achieved by the present disclosure is to provide a stretchable display device capable of simply creating a bypass signal path by using a welding process.

Aspects of the present disclosure are not limited to the above-mentioned aspects, and other aspects, which are not mentioned above, can be clearly understood by those skilled in the art from the following descriptions.

A display device according to one or more embodiments of the present disclosure includes: a substrate, a pattern layer disposed on the substrate and comprising a plurality of pixel plate patterns, a plurality of bypass plate patterns, and a plurality of first line patterns, a plurality of subpixels disposed on the plurality of pixel plate patterns, each of the plurality of subpixels comprising a circuit and a light-emitting element configured to be operated by the circuit, a plurality of lines disposed on the plurality of pixel plate patterns and connected to the circuits, respectively, a plurality of bypass lines disposed on the plurality of pixel plate patterns and the plurality of bypass plate patterns, respectively, and a plurality of connection lines disposed on the plurality of first line patterns, respectively, in which the plurality of first line patterns are disposed between at least some of the plurality of pixel plate patterns and between the plurality of pixel plate patterns and the plurality of bypass plate patterns, respectively, in which some of the plurality of lines on some of the plurality of pixel plate patterns receive signals from corresponding lines of the plurality of lines on one or more adjacent pixel plate patterns, and in which some of the plurality of lines on some of the remaining pixel plate patterns receive signals from corresponding bypass lines of the plurality of bypass lines on some of the plurality of bypass plate patterns, wherein the plurality of pixel plate patterns include the some of the plurality of pixel plate patterns and the remaining pixel plate patterns. The remaining pixel plate patterns do not include the some of the plurality of pixel plate patterns. Therefore, the plurality of bypass lines and the plurality of bypass plate patterns may be used to transmit the signal to the normal subpixel on the pixel plate pattern while inhibiting a signal from being applied to a defective subpixel on some pixel plate patterns.

A display device according to one or more embodiments of the present disclosure includes: a substrate; a pattern layer disposed on the substrate and comprising a plurality of pixel plate patterns, a plurality of bypass plate patterns, and a plurality of first line patterns; a plurality of subpixels disposed on the plurality of pixel plate patterns, each of the plurality of subpixels comprising a circuit and a light-emitting element configured to be operated by the circuit; a plurality of lines disposed on the plurality of pixel plate patterns and connected to the circuits, respectively; a plurality of bypass lines disposed on the plurality of pixel plate patterns and the plurality of bypass plate patterns, respectively; and a plurality of connection lines disposed on the plurality of first line patterns, respectively. The plurality of first line patterns may be disposed between the plurality of pixel plate patterns and between the plurality of pixel plate patterns and the plurality of bypass plate patterns, respectively. Therefore, it is possible to form the bypass path capable of applying a signal to the normal subpixel while bypassing a defective subpixel by using the plurality of bypass lines.

Other detailed matters of the example embodiments are included in the detailed description and the drawings.

According to the present disclosure, it is possible to provide the stretchable display device capable of being transformed into various shapes.

According to the present disclosure, it is possible to suppress an abnormal operation of a defective subpixel by inhibiting a signal from being transmitted to the defective subpixel.

According to the present disclosure, it is possible to suppress a bright spot defect of a defective subpixel by inhibiting a signal from being transmitted to the defective subpixel.

According to the present disclosure, it is possible to form the separate bypass signal path separated from a defective subpixel, thereby easily applying a signal only to the normal subpixel excluding the defective subpixel.

According to the present disclosure, it is possible to simply create the bypass signal path by the welding process.

The effects according to the present disclosure are not limited to the contents provided above, and more various effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a schematic top plan view of a display device according to an embodiment of the present disclosure;

FIG. 2 is an enlarged top plan view of a display area of the display device according to the embodiment of the present disclosure;

FIG. 3 is a cross-sectional view taken along lines A-A′ and B-B′ in FIG. 2;

FIG. 4 is a circuit diagram of a subpixel of the display device according to the embodiment of the present disclosure;

FIG. 5A is a schematic enlarged top plan view of a pixel plate pattern of the display device according to the embodiment of the present disclosure;

FIG. 5B is an enlarged top plan view of the display area of the display device according to the embodiment of the present disclosure;

FIG. 6A is a schematic enlarged top plan view of the pixel plate pattern of the display device according to the embodiment of the present disclosure;

FIG. 6B is an enlarged top plan view of the display area of the display device according to the embodiment of the present disclosure;

FIG. 7 is an enlarged top plan view of a bypass plate pattern of the display device according to the embodiment of the present disclosure;

FIGS. 8A to 9B are cross-sectional views taken along line A-A′ in FIG. 7;

FIG. 10 is a schematic cross-sectional view of a third connection line in areas (1) to (4) in FIG. 2;

FIG. 11 is an enlarged top plan view of the display area of the display device according to the embodiment of the present disclosure; and

FIGS. 12A to 12C are enlarged top plan views of a plurality of bypass plate patterns of the display device according to the embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. In one or more examples, unless stated otherwise, an element may be one or more elements; and an element may include a plurality of elements. In one or more examples, unless stated otherwise, a line may include multiple lines; a signal may include multiple signals; a bypass line may include multiple bypass lines; a connection line may include multiple connection lines; and a pattern may include multiple patterns. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements, unless the context clearly indicates otherwise. Moreover, “at least some,” “some” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element, unless the context clearly indicates otherwise.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

In description of flow of a signal, for example, when a signal is provided (e.g., transferred or transmitted) from a node A to a node B, this may include a case where the signal is provided from the node A to the node B via one or more nodes unless a phrase such as “immediately provided,” “directly provided” or the like is used.

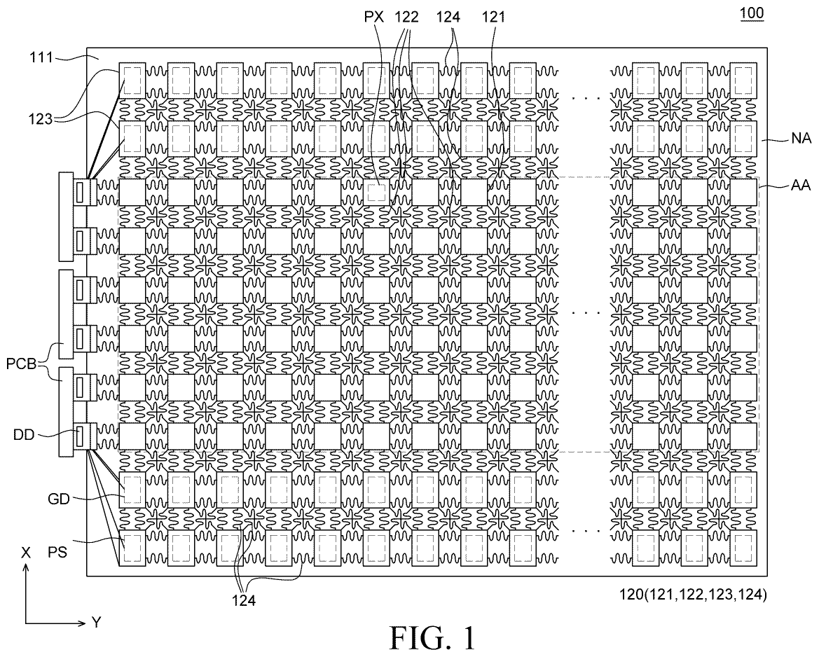

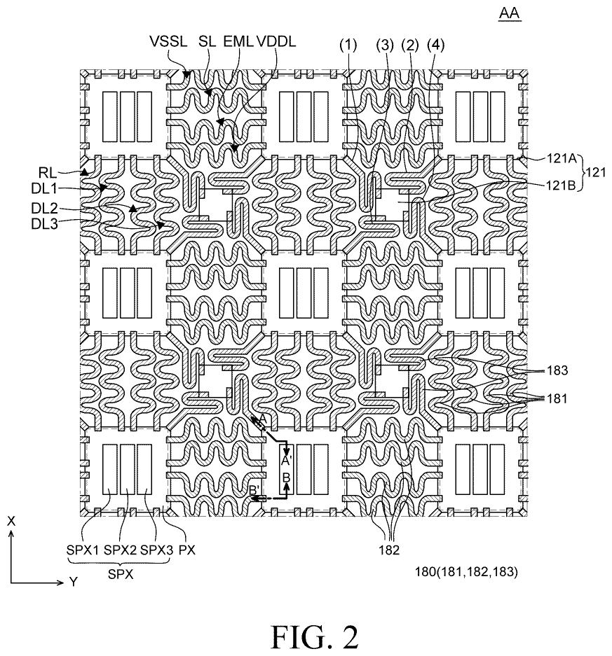

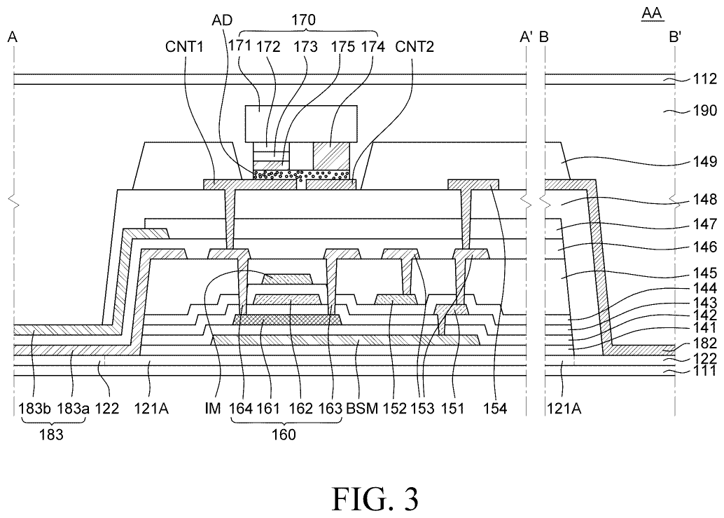

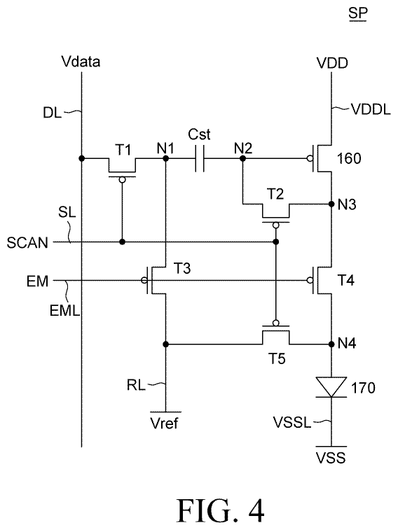

FIG. 1 is a top plan view of a display device according to an embodiment of the present disclosure. FIG. 2 is an enlarged top plan view of a display area of the display device according to the embodiment of the present disclosure. FIG. 3 is a cross-sectional view taken along lines A-A′ and B-B′ in FIG. 2. FIG. 4 is a circuit diagram of a subpixel of the display device according to the embodiment of the present disclosure.

First, a display device 100 according to an embodiment of the present disclosure is a display device 100 capable of displaying images even when being bent or stretched. The display device 100 may also be referred to as a stretchable display device, a flexible display device, an extendable display device, and the like. The display device 100 may have not only high flexibility but also stretchability in comparison with a general display device in the related art. Therefore, a user may bend or stretch the display device 100, and a shape of the display device 100 may be freely changed in accordance with the user's manipulation. For example, in case that the user holds and pulls an end of the display device 100, the display device 100 may be stretched in a direction in which the user pulls the display device. Alternatively, in case that the user disposes the display device 100 on a non-flat outer surface, the display device 100 may be disposed to be curved along a shape of an outer surface of a wall surface. In addition, when the force applied by the user is eliminated, the display device 100 may be restored back to an original shape.

With reference to FIGS. 1 to 3, a lower substrate 111 may support several constituent elements of the display device 100, and an upper substrate 112 may cover several constituent elements of the display device 100.

The lower substrate 111 and the upper substrate 112 may each be a flexible substrate made of an insulating material that is bendable or stretchable. For example, the lower substrate 111 and the upper substrate 112 may each be made of silicone rubber such as polydimethylsiloxane (PDMS) or elastomer such as polyurethane (PU) and polytetrafluoroethylene (PTFE) and thus have flexibility. Further, the lower substrate 111 and the upper substrate 112 may be made of the same material. However, the present disclosure is not limited thereto. The lower substrate 111 and the upper substrate 112 may be variously modified.

The display device 100 or the lower substrate 111 may have, define, or indicate a display area AA in which images are displayed, and a non-display area NA that excludes the display area AA.

The display area AA is an area of the display device 100 in which images are displayed. A plurality of pixels PX, which each include display elements and circuit elements, may be disposed in the display area AA, and gate drivers GD and power supplies PS, which are configured to operate the plurality of pixels PX disposed in the display area AA, may be disposed in the non-display area NA.

A pattern layer 120 is disposed on the lower substrate 111 and includes a plurality of first plate patterns 121 and a plurality of first line patterns 122 disposed in the display area AA, and a plurality of second plate patterns 123 and a plurality of second line patterns 124 disposed in the non-display area NA. For example, the plurality of first plate patterns 121 and the plurality of second plate patterns 123 may be disposed in island shapes spaced apart from one another. The plurality of first line patterns 122 may connect the first plate patterns 121 adjacent to one another, and the plurality of second line patterns 124 may connect the first and second plate patterns 121 and 123 adjacent to one another or connect the plurality of second plate patterns 123 adjacent to one another.

The plurality of pixels PX may be formed on the plurality of first plate patterns 121, and the gate drivers GD and the power supplies PS may be formed on the plurality of second plate patterns 123.

Meanwhile, FIG. 1 illustrates that the plurality of first plate patterns 121 and the plurality of second plate patterns 123 each having a quadrangular shape. However, the present disclosure is not limited thereto.

The plurality of first line patterns 122 and the plurality of second line patterns 124 may each have a curved shape, e.g., a sinusoidal shape. However, the present disclosure is not limited thereto. The plurality of first line patterns 122 and the plurality of second line patterns 124 may each have various shapes such as a shape extending in a zigzag manner or a shape in which a plurality of substrates having rhombic shapes are connected at vertices thereof and extend.

The plurality of first plate patterns 121, the plurality of first line patterns 122, the plurality of second plate patterns 123, and the plurality of second line patterns 124 are each a rigid pattern. For example, the plurality of first plate patterns 121, the plurality of first line patterns 122, the plurality of second plate patterns 123, and the plurality of second line patterns 124 may be more rigid than the lower substrate 111 and the upper substrate 112. For example, the plurality of first plate patterns 121, the plurality of first line patterns 122, the plurality of second plate patterns 123, and the plurality of second line patterns 124 may each be made of a plastic material having lower flexibility than those of the lower substrate 111 and the upper substrate 112. Therefore, the plurality of first plate patterns 121, the plurality of first line patterns 122, the plurality of second plate patterns 123, and the plurality of second line patterns 124 may each have an elastic modulus and hardness higher than an elastic modulus and hardness of the lower substrate 111.

The gate drivers GD may be mounted on the plurality of second plate patterns 123. The gate drivers GD are constituent elements configured to supply gate voltages to the plurality of pixels PX disposed in the display area AA. For example, the gate driver GD includes a plurality of stages formed on each of the plurality of second plate patterns 123. The stages of the gate driver GD may be electrically connected to one another through a plurality of gate connection lines. Therefore, a gate voltage outputted from any one stage may be transmitted to another stage. Further, the stages may sequentially supply the gate voltages to the plurality of pixels PX respectively connected to the stages.

The power supplies PS may be mounted on the plurality of second plate patterns 123. The power supplies PS may be electrically connected to the gate drivers GD and the plurality of pixels PX. For example, the power supply PS may supply a gate drive voltage and a gate clock voltage to the gate driver GD. Further, the power supplies PS may be connected to the plurality of pixels PX and supply pixel drive voltages to the plurality of pixels PX.

A printed circuit board PCB includes a controller, such as an IC chip and a circuit part, a memory, a processor, and/or the like and is configured to transmit signals and voltages for operating the display elements to the display elements from a controller. The printed circuit board PCB may include a stretchable area and a non-stretchable area to ensure stretchability. For example, IC chips, circuit parts, memories, processors, and the like may be mounted in the non-stretchable area. Lines electrically connected to the IC chips, the circuit parts, the memories, and the processors may be disposed in the stretchable area.

A data driver DD is a constituent element configured to supply data voltages Vdata to the plurality of pixels PX disposed in the display area AA. The data driver DD may be configured in the form of an IC chip, and thus referred to as a data integrated circuit (D-IC).

With reference to FIGS. 2 and 3, the plurality of first plate patterns 121 is disposed on the lower substrate 111 in the display area AA. The plurality of first plate patterns 121 include a plurality of pixel plate patterns 121A and a plurality of bypass plate patterns 121B.

The plurality of pixel plate patterns 121A is substrates on which the pixels PX including a plurality of subpixels SPX are formed. The plurality of pixel plate patterns 121A may be disposed in a matrix shape while being disposed in a plurality of rows and a plurality of columns. The plurality of pixel plate patterns 121A may be arranged in a first direction X and a second direction Y.

The plurality of subpixels SPX may include a first subpixel SPX1, a second subpixel SPX2, and a third subpixel SPX3. For example, any one of the first subpixel SPX1, the second subpixel SPX2, and the third subpixel SPX3 may be a red subpixel SPX, another subpixel may be a green subpixel SPX, and the remaining subpixel may be a blue subpixel SPX. However, the present disclosure is not limited thereto.

The plurality of subpixels SPX may each include a light-emitting element 170, and a driving transistor 160 configured to operate the light-emitting element 170. The light-emitting element 170 may be any one of a light-emitting diode (LED) or a micro-light-emitting diode (micro-LED). However, an organic light-emitting diode (OLED) may be used as the light-emitting element 170. However, the present disclosure is not limited thereto.

The plurality of bypass plate patterns 121B is disposed in areas between the plurality of pixel plate patterns 121A. The plurality of bypass plate patterns 121B and the plurality of pixel plate patterns 121A may be disposed in different rows and different columns.

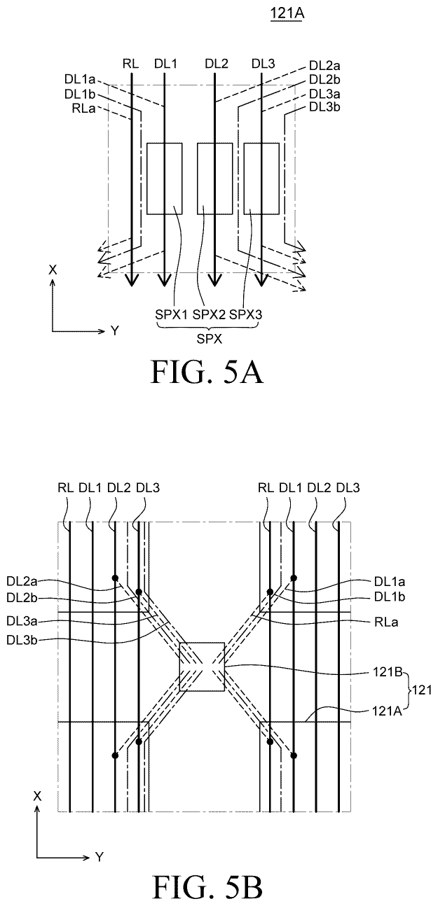

A plurality of bypass lines is disposed on the plurality of bypass plate patterns 121B. When the pixel plate pattern 121A having a defective subpixel (XSPX) is detected, all the first line pattern 122, a first connection line 181, and a second connection line 182 connected to the pixel plate pattern 121A, may be removed, thereby suppressing a bright spot defect. For instance, such pattern and lines 122, 181 and 182 (or portions thereof) may be separated, removed or cut off from the pixel plate pattern 121A, using, e.g., laser beams. For example, the defective subpixel XSPX may be caused by various types of foreign substances, a transfer defect of the light-emitting element 170, a defect of the light-emitting element 170, a defect of a circuit of the subpixel SPX, and the like. In this case, a signal to be transmitted to the defective subpixel XSPX may be blocked, thereby minimizing a bright spot defect or the like that may occur in the defective subpixel XSPX. That is, a path through which a signal is applied to the defective subpixel XSPX may be removed, thereby reducing a bright spot defect in which the defective subpixel XSPX continuously emits light. In this case, the plurality of bypass lines may be used to normally apply signals to the pixel plate patterns 121A disposed in the same row and the same column as the pixel plate pattern 121A having the defective subpixel XSPX. A repair method using the plurality of bypass lines will be described below in more detail with reference to FIGS. 5A to 12C.

Meanwhile, a size of the bypass plate pattern 121B may be smaller than a size of the pixel plate pattern 121A. Only the plurality of bypass lines is disposed on the bypass plate pattern 121B, whereas a plurality of transistors, a plurality of capacitors, a plurality of light-emitting elements 170, and the like, which constitute the plurality of subpixels SPX, are disposed on the pixel plate pattern 121A. Therefore, the size of the pixel plate pattern 121A may be larger than the size of the bypass plate pattern 121B.

The plurality of first line patterns 122 is disposed between the plurality of first plate patterns 121. The plurality of first line patterns 122 may be disposed between the plurality of pixel plate patterns 121A and between the plurality of pixel plate patterns 121A and the plurality of bypass plate patterns 121B. For example, some of the plurality of first line patterns 122 may be disposed between the plurality of pixel plate patterns 121A and extend in the first direction X and the second direction Y. The remaining first line patterns 122, among the plurality of first line patterns 122, may be disposed between the plurality of pixel plate patterns 121A and the plurality of bypass plate patterns 121B and extend in directions different from the first direction X and the second direction Y.

A plurality of connection lines 180 is disposed on the plurality of first line patterns 122. The plurality of connection lines 180 includes a plurality of first connection lines 181, a plurality of second connection lines 182, and a plurality of third connection lines 183.

The plurality of first connection lines 181 may be lines disposed between the plurality of pixel plate patterns 121A and extending in the first direction X, and the plurality of second connection lines 182 may be disposed between the plurality of pixel plate patterns 121A and extend in the second direction Y. Therefore, the plurality of first connection lines 181 and the plurality of second connection lines 182 may connect a plurality of lines on the pixel plate pattern 121A. For example, the plurality of first connection lines 181 extending in the first direction X may connect a reference line RL, a first data line DL1, a second data line DL2, and a third data line DL3 on the pixel plate pattern 121A. For example, the plurality of second connection lines 182 extending in the second direction Y may connect a low-potential power line VSSL, a scan line SL, a light emission control line EML, and a high-potential power line VDDL on the pixel plate pattern 121A.

In this case, the first data line DL1, the second data line DL2, and the third data line DL3 may be data lines DL respectively connected to the first subpixel SPX1, the second subpixel SPX2, and the third subpixel SPX3.

Next, the plurality of third connection lines 183 may be disposed between the plurality of pixel plate patterns 121A and the plurality of bypass plate patterns 121B and extend in directions different from the first direction X and the second direction Y. For example, the plurality of third connection line 183 may extend in a direction oblique to both the first and second directions. For example, the third connection line 183 may extend to a corner of the bypass plate pattern 121B adjacent to one of four corners of the pixel plate pattern 121A. The plurality of third connection lines 183 may connect the plurality of bypass lines on the pixel plate pattern 121A to the plurality of bypass lines on the bypass plate pattern 121B.

Hereinafter, a cross-sectional structure on the pixel plate pattern 121A will be described with reference to FIG. 3.

A multi-buffer layer 141 is disposed on the pixel plate pattern 121A, and an active buffer layer 142 is disposed on the multi-buffer layer 141. The multi-buffer layer 141 and the active buffer layer 142 may reduce the permeation of moisture or impurities into the lower substrate 111 and the pixel plate pattern 121A from the outside, thereby protecting various constituent elements of the display device 100. For example, the multi-buffer layer 141 and the active buffer layer 142 may each be configured as a single layer or multilayer made of silicon nitride (SiNx), silicon oxide (SiOx), and silicon oxynitride (SiON). However, the present disclosure is not limited thereto.

A light-blocking layer BSM is disposed between the multi-buffer layer 141 and the active buffer layer 142. The light-blocking layer BSM may block light entering an active layer 161 of the driving transistor 160, which will be described below, from a lower side of the substrate, thereby minimizing a leakage current from the driving transistor 160.

The driving transistor 160 is disposed on the active buffer layer 142. The driving transistor 160 includes the active layer 161, a gate electrode 162, a source electrode 163, and a drain electrode 164.

The active layer 161 is disposed on the active buffer layer 142. The active layer 161 may be made of a semiconductor material such as an oxide semiconductor, amorphous silicon, or polysilicon. However, the present disclosure is not limited thereto.

A gate insulation layer 143 is disposed on the active layer 161. The gate insulation layer 143 is an insulation layer for insulating the active layer 161 and the gate electrode 162. The gate insulation layer 143 may be configured as a single layer or multilayer made of silicon oxide (SiOx) or silicon nitride (SiNx). However, the present disclosure is not limited thereto.

The gate electrode 162 is disposed on the gate insulation layer 143. The gate electrode 162 may be configured as a single layer or multilayer structure made of an electrically conductive material, e.g., copper (Cu), aluminum (Al), molybdenum (Mo), nickel (Ni), titanium (Ti), gold (Au), chromium (Cr), or an alloy thereof. However, the present disclosure is not limited thereto.

A first interlayer insulation layer 144 is disposed on the gate electrode 162, and a second interlayer insulation layer 145 is disposed on the first interlayer insulation layer 144. The first interlayer insulation layer 144 and the second interlayer insulation layer 145 are insulation layers for protecting components disposed below the first interlayer insulation layer 144 and the second interlayer insulation layer 145. The first interlayer insulation layer 144 and the second interlayer insulation layer 145 may each be configured as a single layer or multilayer made of silicon oxide (SiOx) or silicon nitride (SiNx). However, the present disclosure is not limited thereto.

The source electrode 163 and the drain electrode 164 are disposed on the second interlayer insulation layer 145. The source electrode 163 and the drain electrode 164 may be electrically connected to the active layer 161 through contact holes formed in the second interlayer insulation layer 145, the first interlayer insulation layer 144, and the gate insulation layer 143. The source electrode 163 and the drain electrode 164 may each be made of an electrically conductive material. However, the present disclosure is not limited thereto.

Next, an intermediate metal layer IM is disposed on the first interlayer insulation layer 144. The intermediate metal layer IM and the gate electrode 162 of the driving transistor 160 may overlap each other and constitute a storage capacitor.

A third interlayer insulation layer 146 is disposed on the driving transistor 160, and a passivation layer 147 is disposed on the third interlayer insulation layer 146. The third interlayer insulation layer 146 and the passivation layer 147 are insulation layers for protecting components disposed below the third interlayer insulation layer 146 and the passivation layer 147. The third interlayer insulation layer 146 and the passivation layer 147 may each be configured as a single layer or multilayer made of silicon oxide (SiOx) or silicon nitride (SiNx). However, the present disclosure is not limited thereto.

A planarization layer 148 is disposed on the passivation layer 147. The planarization layer 148 may planarize an upper portion of the pixel plate pattern 121A on which a plurality of conductive layers, the driving transistor 160, and a plurality of lines are disposed. The planarization layer 148 may be configured as a single layer or a plurality of layers made of an organic material. For example, the planarization layer 148 may be made of a photoresist or an acrylic-based organic material. However, the present disclosure is not limited thereto.

Meanwhile, at least any one of the multi-buffer layer 141, the active buffer layer 142, the gate insulation layer 143, the first interlayer insulation layer 144, the second interlayer insulation layer 145, the third interlayer insulation layer 146, and the passivation layer 147 may be made of an inorganic insulating material among insulating materials. For this reason, the display device 100 may be easily cracked and damaged during the process of stretching the display device 100. Therefore, the multi-buffer layer 141, the active buffer layer 142, the gate insulation layer 143, the first interlayer insulation layer 144, the second interlayer insulation layer 145, the third interlayer insulation layer 146, and the passivation layer 147 may be formed only above the plurality of first plate patterns 121 by being patterned in the form of the plurality of first plate patterns 121 without being formed in the area between the plurality of first plate patterns 121.

The planarization layer 148 may be disposed to cover top and side surfaces of the multi-buffer layer 141, the active buffer layer 142, the gate insulation layer 143, the first interlayer insulation layer 144, the second interlayer insulation layer 145, the third interlayer insulation layer 146, and the passivation layer 147 on the plurality of first plate patterns 121. Therefore, the planarization layer 148 may compensate for level differences between the side surfaces of the multi-buffer layer 141, the active buffer layer 142, the gate insulation layer 143, the first interlayer insulation layer 144, the second interlayer insulation layer 145, the third interlayer insulation layer 146, and the passivation layer 147. Further, the planarization layer 148 may increase bonding strength with the plurality of connection lines 180 disposed on the side surface of the planarization layer 148.

A first connection pad CNT1 and a second connection pad CNT2 are disposed on the planarization layer 148. The first connection pad CNT1 and the second connection pad CNT2 are electrodes for electrically connecting the light-emitting element 170 to the driving transistor 160 and the power line. For example, the first connection pad CNT1 may electrically connect a p-electrode 175 of the light-emitting element 170 to the driving transistor 160, and the second connection pad CNT2 may electrically connect an n-electrode 174 of the light-emitting element 170 to the power line.

A bonding layer AD is disposed on the first connection pad CNT1 and the second connection pad CNT2. The light-emitting element 170 may be bonded to the first connection pad CNT1 and the second connection pad CNT2 by the bonding layer AD.

The bonding layer AD may be a conductive bonding pattern made by dispersing conductive balls into an insulating base member. Therefore, in case that heat or pressure is applied to the bonding layer AD, the conductive balls are electrically connected in a portion to which heat or pressure is applied, such that the bonding layer AD has conductive properties. An area, which is not pressed, may have insulation properties.

The light-emitting element 170 is disposed on the bonding layer AD. The light-emitting element 170 includes an n-type layer 171, an active layer 172, a p-type layer 173, the n-electrode 174, and the p-electrode 175. The light-emitting element 170 of the display device 100 according to the embodiment of the present disclosure has a flip-chip structure having the n-electrode 174 and the p-electrode 175 formed on one surface thereof.

The n-type layer 171 may also be disposed on a separate base substrate made of a material capable of transmitting light. The active layer 172 is disposed on the n-type layer 171. The active layer 172 may be a light-emitting layer provided in the light-emitting element 170 and configured to emit light. The p-type layer 173 may be disposed on the active layer 172.

The light-emitting element 170 of the display device 100 according to the embodiment of the present disclosure is manufactured by sequentially stacking the n-type layer 171, the active layer 172, and the p-type layer 173, etching a predetermined portion, and then forming the n-electrode 174 and the p-electrode 175.

The n-electrode 174 may be disposed in the area etched as described above. The n-electrode 174 may be made of an electrically conductive material. Further, the p-electrode 175 may be disposed in a non-etched area. The p-electrode 175 may also be made of an electrically conductive material. For example, the n-electrode 174 is disposed on the n-type layer 171 exposed by the etching process, and the p-electrode 175 is disposed on the p-type layer 173. The p-electrode 175 may be made of the same material as the n-electrode 174.

A bank 149 is disposed on the planarization layer 148. The bank 149 is a constituent element that separates the adjacent subpixels SPX. The bank 149 may be disposed between the plurality of light-emitting elements 170 and suppress a color mixture.

Meanwhile, various conductive layers may be further disposed on the pixel plate pattern 121A. For example, a first conductive layer 151 may be disposed on the gate insulation layer 143, and a second conductive layer 152 may be disposed on the first interlayer insulation layer 144. Further, a third conductive layer 153 may be disposed on the second interlayer insulation layer 145, and a fourth conductive layer 154 may be disposed on the planarization layer 148. The plurality of conductive layers may be included in any one of the plurality of lines, the plurality of transistors, and the plurality of capacitors.

A filling layer 190 is disposed between the lower substrate 111 and the upper substrate 112. The filling layer 190 may be disposed on an entire surface of the lower substrate 111, and a space between the constituent elements disposed on the upper substrate 112 and the lower substrate 111 may be filled with the filling layer 190. The filling layer 190 may be made of a curable bonding agent.

Next, the plurality of connection lines 180 may extend from the first line pattern 122 onto the pixel plate pattern 121A and be connected to the plurality of lines on the pixel plate pattern 121A. For example, the first connection line 181 and the second connection line 182 may extend from the first line pattern 122 onto the planarization layer 148 of the pixel plate pattern 121A. The first connection lines 181 may be connected to the reference line RL and the plurality of data lines DL, and the second connection lines 182 may be connected to the low-potential power line VSSL, the scan line SL, the light emission control line EML, and the high-potential power line VDDL.

The third connection line 183 includes a third upper connection line 183b and a third lower connection line 183a. The third connection line 183 may have a dual line structure including the third upper connection line 183b and the third lower connection line 183a. The third interlayer insulation layer 146 is disposed on the third lower connection line 183a, and the third upper connection line 183b is disposed on the third interlayer insulation layer 146. The third lower connection line 183a may extend from the first line pattern 122 onto the second interlayer insulation layer 145 of the pixel plate pattern 121A. The third upper connection line 183b may extend from the first line pattern 122 onto the third interlayer insulation layer 146 of the pixel plate pattern 121A. The third connection line 183 may extend from the first line pattern 122 onto the pixel plate pattern 121A and be connected to any one of the plurality of lines on the pixel plate pattern 121A or be disposed to be spaced apart from the plurality of lines. The third connection line 183 will be described below in more detail with reference to FIGS. 5A and 5B.

In this case, the drawings illustrate that the third upper connection line 183b extends onto the third interlayer insulation layer 146 of the pixel plate pattern 121A, and the third lower connection line 183a extends onto the second interlayer insulation layer 145 of the pixel plate pattern 121A. However, these lines may extend to other insulation layers among the plurality of insulation layers on the pixel plate pattern 121A. However, the present disclosure is not limited thereto. In addition, the drawings illustrate that the third interlayer insulation layer 146 extending from the pixel plate pattern 121A is disposed between the third upper connection line 183b and the third lower connection line 183a. However, another insulation layer may be disposed between the third upper connection line 183b and the third lower connection line 183a. However, the present disclosure is not limited thereto.

Meanwhile, in the case of a general display device, various lines such as a plurality of scan lines and a plurality of data lines are disposed between a plurality of subpixels and extend in straight line shapes. The plurality of subpixels is connected to the single signal line. Therefore, in the case of the general display device, various lines such as the scan line, the data line, the power line, and the reference line extend in a direction from one side to the other side without interruption on the substrate.

On the contrary, in the case of the display device 100 according to the embodiment of the present disclosure, various lines, such as the scan line SL, the data line DL, the power line, and the reference line RL, which are straight lines that may be considered as being used for the general display device, are disposed only on the plurality of first plate patterns 121 and the plurality of second plate patterns 123. That is, in the display device 100 according to the embodiment of the present disclosure, the straight line is disposed only on the plurality of first plate patterns 121 and the plurality of second plate patterns 123. Further, in the display device 100 according to the embodiment of the present disclosure, the lines on the two adjacent first plate patterns 121 may be connected by the plurality of connection lines 180. Therefore, the plurality of connection lines 180 electrically connect the lines on the two adjacent first plate patterns 121.

Meanwhile, the circuit of the subpixel SPX configured to operate the light-emitting element 170 may be configured variously. For example, the circuit of the subpixel SPX may include various transistors and capacitors in addition to the driving transistor 160. The configuration of the plurality of lines may vary depending on the configuration of the circuit of the subpixel SPX.

For example, as illustrated in FIG. 4, in case that the circuit of the subpixel SPX includes the light-emitting element 170, a first transistor T1, a second transistor T2, a third transistor T3, a fourth transistor T4, a fifth transistor T5, the driving transistor 160, and a capacitor Cst, the subpixel SPX may be connected to the scan line SL, the data line DL, the light emission control line EML, the reference line RL, the high-potential power line VDDL, and the low-potential power line VSSL.

First, the first transistor T1 is disposed between the data line DL and a first node N1. The first transistor T1 may be turned on by a scan signal SCAN of the scan line SL and transmit a voltage of the data line DL to the first node N1.

The second transistor T2 is disposed between a second node N2 and a third node N3. The second transistor T2 may be turned on by the scan signal SCAN of the scan line SL and connect the second node N2 and the third node N3.

The third transistor T3 is disposed between the first node N1 and the reference line RL. The third transistor T3 may be turned on by a light emission control signal EM of the light emission control line EML and transmit a reference voltage Vref to the first node N1.

The fourth transistor T4 is disposed between the third node N3 and a fourth node N4. The fourth transistor T4 may be turned on by the light emission control signal EM of the light emission control line EML and connect the third node N3 and the fourth node N4.

The fifth transistor T5 is disposed between the reference line RL and the fourth node N4. The fifth transistor T5 may be turned on by the scan signal SCAN of the scan line SL and transmit the reference voltage Vref to the fourth node N4.

The driving transistor 160 is disposed between the high-potential power line VDDL and the third node N3. The driving transistor 160 may control a drive current that passes through the third node N3 and the fourth node N4 and flows to the light-emitting element 170. Further, the gate electrode 162 and the drain electrode 164 of the driving transistor 160 may be respectively connected to the second node N2 and the third node N3, and the driving transistor 160 may change to a diode connection state when the second transistor T2 is turned on.

The capacitor Cst is disposed between the first node N1 and the second node N2. The capacitor Cst may maintain a constant voltage of the gate electrode 162 of the driving transistor 160 while the light-emitting element 170 emits light.

The light-emitting element 170 is disposed between the fourth node N4 and the low-potential power line VSSL. The light-emitting element 170 may emit light by using the drive current from the driving transistor 160.

Hereinafter, the description will be made on the assumption that the plurality of subpixels SPX is connected to the scan line SL, the data line DL, the light emission control line EML, the reference line RL, the high-potential power line VDDL, and the low-potential power line VSSL.

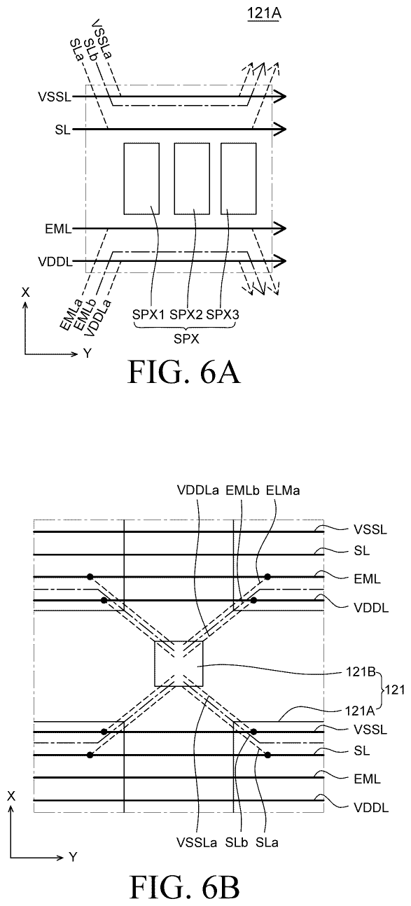

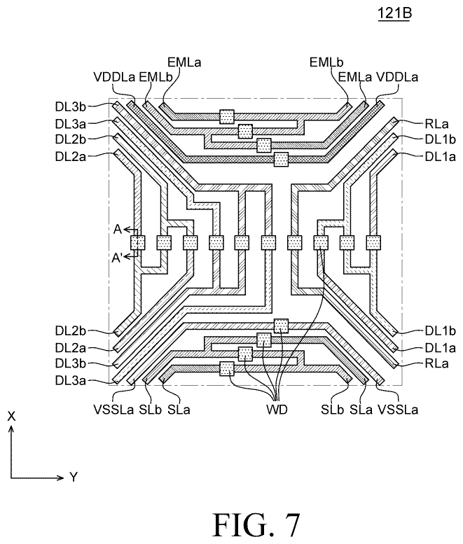

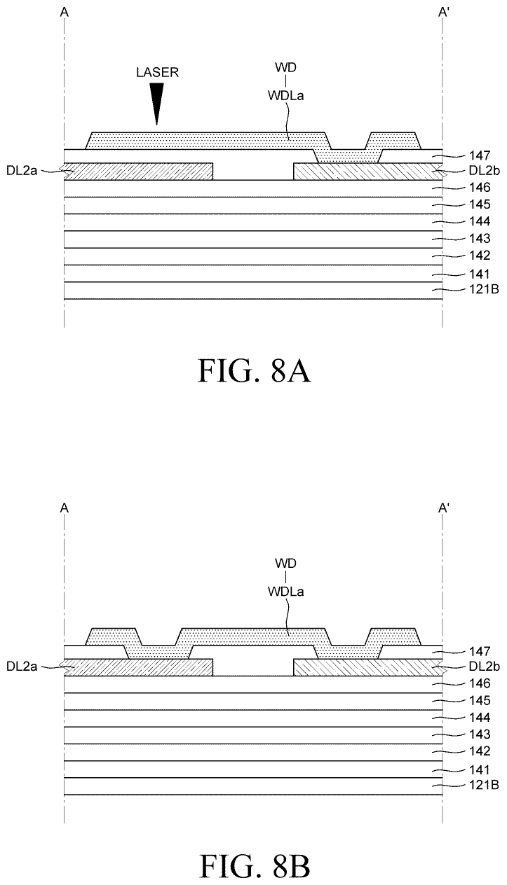

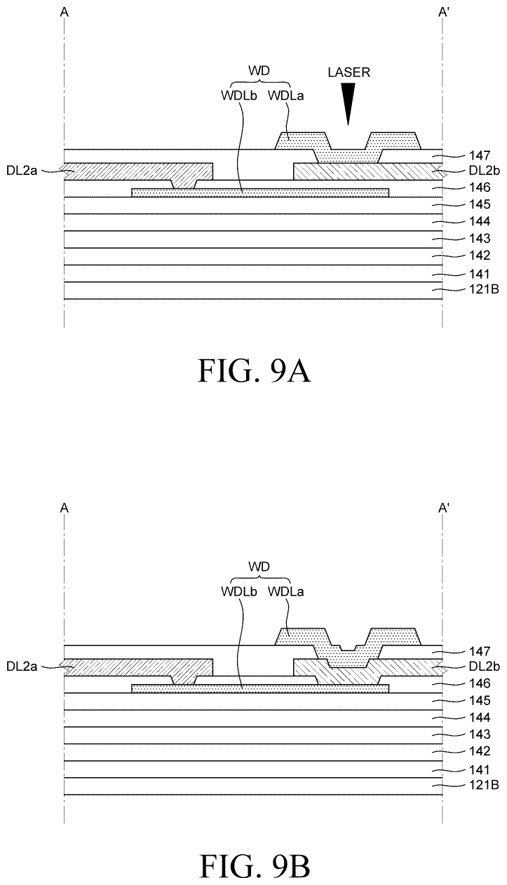

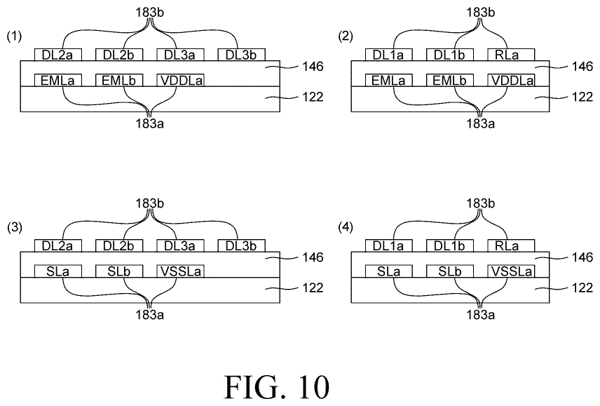

FIG. 5A is a schematic enlarged top plan view of the pixel plate pattern of the display device according to the embodiment of the present disclosure. FIG. 5B is an enlarged top plan view of the display area of the display device according to the embodiment of the present disclosure. FIG. 6A is a schematic enlarged top plan view of the pixel plate pattern of the display device according to the embodiment of the present disclosure. FIG. 6B is an enlarged top plan view of the display area of the display device according to the embodiment of the present disclosure. FIG. 7 is an enlarged top plan view of the bypass plate pattern of the display device according to the embodiment of the present disclosure. FIGS. 8A to 9B are cross-sectional views taken along line A-A′ in FIG. 7. FIG. 10 is a schematic cross-sectional view of the third connection line in areas (1) to (4) in FIG. 2.

Specifically, FIGS. 5A and 5B are views for explaining lines extending in the first direction X and bypass lines thereof, FIGS. 6A and 6B are views for explaining lines extending in the second direction Y and bypass lines thereof, FIGS. 8A and 8B are views for explaining one embodiment of a welding portion WD, and FIGS. 9A and 9B are views for explaining another embodiment of the welding portion WD. For convenience of description, in FIGS. 5A to 6B, the plurality of lines is illustrated as thick solid lines, a first type bypass line of the plurality of bypass lines is illustrated as a dotted line, and a second type bypass line of the plurality of bypass lines is illustrated as a one-dot chain line. In addition, FIG. 10 illustrates the bypass lines connected by the third connection line 183 together with reference numerals thereof.

With reference to FIGS. 5A to 6B, the plurality of bypass lines is disposed on the pixel plate pattern 121A and the bypass plate pattern 121B, and the plurality of lines is disposed on the pixel plate pattern 121A. The plurality of lines may be lines for applying signals directly to the plurality of subpixels SPX. The plurality of bypass lines may be lines that receive signals from the plurality of lines and transmit the signals to the normal subpixel SPX and the lines of the adjacent pixel plate patterns 121A when the defective subpixel XSPX occurs.

The plurality of bypass lines may include the first type bypass line and the second type bypass line. The first type bypass line may be connected directly to the plurality of lines and receive the signal. The signal transmitted from another bypass line to the first type bypass line may be transmitted to the line connected to the first type bypass line, such that the circuit of the subpixel SPX connected to the line may operate. The second type bypass line connected to the first type bypass line may be separated from the plurality of lines and the circuit of the subpixel SPX and connected only to the first type bypass line. The second type bypass line may receive the signal from the first type bypass line and transmit the signal to another first type bypass line or the second type bypass line. The second type bypass line may inhibit some signals from being applied to some defective subpixels XSPX. If a signal is applied to the defective subpixel XSPX, a bright spot defect in which the defective subpixel XSPX continuously emits light may occur. Therefore, the second type bypass line may inhibit a signal from being transmitted to the defective subpixel XSPX.

In this case, for each of the plurality of lines, only the first type bypass line may be formed, or both the first type bypass line and the second type bypass line may be formed. For example, only the first type bypass line may be used to form signal bypass paths of the high-potential power line VDDL, the low-potential power line VSSL, and the reference line RL that apply a common voltage to the subpixel SPX. For example, both the first type bypass line and the second type bypass line may be used to form signal bypass paths of the scan line SL and the light emission control line EML for controlling an operation timing of the subpixel SPX or form signal bypass paths of the first data line DL1, the second data line DL2, and the third data line DL3 that apply different voltages to the subpixels SPX. Therefore, the second type bypass line may be used to form the signal bypass paths of at least some lines among the plurality of lines, thereby suppressing a bright spot defect by inhibiting signals from being applied to some defective subpixels XSPX.

With reference to FIGS. 5A and 5B, the reference line RL, the first data line DL1, the second data line DL2, and the third data line DL3 extend in the first direction X on the pixel plate pattern 121A. Two opposite ends of each of the reference line RL, the first data line DL1, the second data line DL2, and the third data line DL3 may be connected to the plurality of first connection lines 181.

A bypass reference line RLa, a first-first bypass data line DL1a, a first-second bypass data line DL1b, a second-first bypass data line DL2a, a second-second bypass data line DL2b, a third-first bypass data line DL3a, and a third-second bypass data line DL3b are disposed on the pixel plate pattern 121A. Two opposite ends of each of the plurality of bypass lines may be connected to the plurality of third connection lines 183. In this case, the bypass reference line RLa, the first-first bypass data line DL1a, the second-first bypass data line DL2a, and the third-first bypass data line DL3a may be the first type bypass lines connected directly to the existing lines and configured to receive signals, and the first-second bypass data line DL1b, the second-second bypass data line DL2b, and the third-second bypass data line DL3b may be the second type bypass lines configured to receive signals from the first type bypass lines.

The bypass reference line RLa may be electrically connected to the reference line RL. For example, the bypass reference line RLa may be connected to the reference line RL and receive the reference voltage Vref. One end of the bypass reference line RLa may extend to a left upper end corner of the pixel plate pattern 121A, and the other end of the bypass reference line RLa may extend to a left lower end corner of the pixel plate pattern 121A and be connected to the third connection line 183.

The first-first bypass data line DL1a may be electrically connected to the first data line DL1, and the first-second bypass data line DL1b may be disposed to be separated from the first data line DL1 and the first-first bypass data line DL1a. The first-first bypass data line DL1a may be connected directly to the first data line DL1 and receive a first data voltage. The first-second bypass data line DL1b may be disposed to be spaced apart from the first data line DL1 and separated from a circuit of the first subpixel SPX1 on the same pixel plate pattern 121A. That is, the signal from the first-second bypass data line DL1b may not be applied to the circuit of the first subpixel SPX1 on the same pixel plate pattern 121A. One end of each of the first-first bypass data line DL1a and the first-second bypass data line DL1b may extend to the left upper end corner of the pixel plate pattern 121A, and the other end of each of the first-first bypass data line DL1a and the first-second bypass data line DL1b may extend to the left lower end corner of the pixel plate pattern 121A and be connected to the third connection line 183.

The second-first bypass data line DL2a may be electrically connected to the second data line DL2, and the second-second bypass data line DL2b may be disposed to be separated from the second data line DL2 and the second-first bypass data line DL2a. The second-first bypass data line DL2a may be connected to the second data line DL2 and receive a second data voltage, and the second-second bypass data line DL2b may be disposed to be spaced apart from the second data line DL2 and separated from a circuit of the second subpixel SPX2. The signal from the second-second bypass data line DL2b may not be applied directly to the circuit of the second subpixel SPX2 on the same pixel plate pattern 121A. One end of each of the second-first bypass data line DL2a and the second-second bypass data line DL2b may extend to a right upper end corner of the pixel plate pattern 121A, and the other end of each of the second-first bypass data line DL2a and the second-second bypass data line DL2b may extend to a right lower end corner of the pixel plate pattern 121A and be connected to the third connection line 183.

The third-first bypass data line DL3a may be electrically connected to the third data line DL3, and the third-second bypass data line DL3b may be disposed to be separated from the third data line DL3 and the third-first bypass data line DL3a. The third-first bypass data line DL3a may be connected to the third data line DL3 and receive a third data voltage, and the third-second bypass data line DL3b may be disposed to be spaced apart from the third data line DL3 and separated from a circuit of the third subpixel SPX3. The signal from the third-second bypass data line DL3b may not be applied to the circuit of the third subpixel SPX3 on the same pixel plate pattern 121A. One end of each of the third-first bypass data line DL3a and the third-second bypass data line DL3b may extend to the right upper end corner of the pixel plate pattern 121A, and the other end of each of the third-first bypass data line DL3a and the third-second bypass data line DL3b may extend to the right lower end corner of the pixel plate pattern 121A and be connected to the third connection line 183.

With reference to FIGS. 6A and 6B, the low-potential power line VSSL, the scan line SL, the light emission control line EML, and the high-potential power line VDDL extend in the second direction Y on the pixel plate pattern 121A. Two opposite ends of each of the low-potential power line VSSL, the scan line SL, the light emission control line EML, and the high-potential power line VDDL may be connected to the plurality of second connection lines 182.

A bypass low-potential power line VSSLa, a first bypass scan line SLa, a second bypass scan line SLb, a first bypass light emission control line EMLa, a second bypass light emission control line EMLb, and a bypass high-potential power line VDDLa are disposed on the pixel plate pattern 121A. The two opposite ends of each of the plurality of bypass lines may be connected to the plurality of third connection lines 183. In this case, the first bypass scan line SLa, the first bypass light emission control line EMLa, the bypass low-potential power line VSSLa, and the bypass high-potential power line VDDLa may be the first type bypass lines, and the second bypass scan line SLb and the second bypass light emission control line EMLb may be the second type bypass lines.

The bypass low-potential power line VSSLa may be electrically connected to the low-potential power line VSSL. For example, the bypass low-potential power line VSSLa may be connected to the low-potential power line VSSL and receive a low-potential power voltage VSS. One end of the bypass low-potential power line VSSLa may extend to the left upper end corner of the pixel plate pattern 121A, and the other end of the bypass low-potential power line VSSLa may extend to the right upper end corner of the pixel plate pattern 121A and be connected to the third connection line 183.

The first bypass scan line SLa may be electrically connected to the scan line SL, and the second bypass scan line SLb may be disposed to be spaced apart from the scan line SL and the first bypass scan line SLa. The first bypass scan line SLa may be connected to the scan line SL and receive the scan signal SCAN, the second bypass scan line SLb may be separated from the scan line SL and the plurality of subpixels SPX, and the signal from the second bypass scan line SLb may not be applied directly to the subpixel SPX on the same pixel plate pattern 121A. One end of each of the first bypass scan line SLa and the second bypass scan line SLb may extend to the left upper end corner of the pixel plate pattern 121A, and the other end of each of the first bypass scan line SLa and the second bypass scan line SLb may extend to the right upper end corner of the pixel plate pattern 121A and be connected to the third connection line 183.

The first bypass light emission control line EMLa may be electrically connected to the light emission control line EML, and the second bypass light emission control line EMLb may be disposed to be spaced apart from the light emission control line EML and the first bypass light emission control line EMLa. The first bypass light emission control line EMLa may be connected to the light emission control line EML and receive the light emission control signal EM, the second bypass light emission control line EMLb may be separated from the light emission control line EML and the plurality of subpixels SPX, and the signal from the second bypass light emission control line EMLb may not be applied directly to the subpixel SPX on the same pixel plate pattern 121A. One end of each of the first bypass light emission control line EMLa and the second bypass light emission control line EMLb may extend to the left lower end corner of the pixel plate pattern 121A, and the other end of each of the first bypass light emission control line EMLa and the second bypass light emission control line EMLb may extend to the right lower end corner of the pixel plate pattern 121A and be connected to the third connection line 183.

The bypass high-potential power line VDDLa may be electrically connected to the high-potential power line VDDL. For example, the bypass high-potential power line VDDLa may be connected to the high-potential power line VDDL and receive a high-potential power voltage VDD. One end of the bypass high-potential power line VDDLa may extend to the left lower end corner of the pixel plate pattern 121A, and the other end of the bypass high-potential power line VDDLa may extend to the right lower end corner of the pixel plate pattern 121A and be connected to the third connection line 183.

With reference to FIG. 7, the plurality of bypass lines is disposed on the bypass plate pattern 121B. Specifically, the bypass reference line RLa, the first-first bypass data line DL1a, the first-second bypass data line DL1b, the second-first bypass data line DL2a, the second-second bypass data line DL2b, the third-first bypass data line DL3a, the third-second bypass data line DL3b, the bypass low-potential power line VSSLa, the first bypass scan line SLa, the second bypass scan line SLb, the first bypass light emission control line EMLa, the second bypass light emission control line EMLb, and the bypass high-potential power line VDDLa are disposed on the bypass plate pattern 121B.

Further, two bypass lines of the same type extending from the different pixel plate patterns 121A and the third connection lines 183 may be disposed on one bypass plate pattern 121B. That is, a pair of bypass lines, to which the same signal is applied, may be disposed on one bypass plate pattern 121B. For example, a pair of bypass reference lines RLa, a pair of first-first bypass data lines DL1a, a pair of first-second bypass data lines DL1b, a pair of second-first bypass data lines DL2a, a pair of second-second bypass data lines DL2b, a pair of third-first bypass data lines DL3a, a pair of third-second bypass data lines DL3b, a pair of bypass low-potential power lines VSSLa, a pair of first bypass scan lines SLa, a pair of second bypass scan lines SLb, a pair of first bypass light emission control lines EMLa, a pair of second bypass light emission control lines EMLb, and a pair of bypass high-potential power lines VDDLa may be disposed on one bypass plate pattern 121B.

Further, the welding portion WD may be disposed between the pair of bypass lines extending from the different pixel plate patterns 121A and the different third connection lines 183. The welding portion WD is configured to selectively connect the pair of bypass lines. The pair of bypass lines may be disposed to at least partially overlap each other with the welding portion WD interposed therebetween. In this case, in case that a welding process is performed by irradiating the welding portion WD with laser beams LASER, the pair of bypass lines may be electrically connected to each other. Therefore, the signal bypass path may be formed by connecting the pair of bypass lines by irradiating the welding portion WD with the laser beams LASER.

For example, the pair of bypass reference lines RLa may include one bypass reference line RLa extending toward the welding portion WD from the right upper end corner of the bypass plate pattern 121B, and the remaining bypass reference line RLa extending toward the welding portion WD from the right lower end corner of the bypass plate pattern 121B. Further, the welding portion WD may be disposed between one bypass reference line RLa and the remaining bypass reference line RLa, and the pair of bypass reference lines RLa may be connected to each other in case that the welding process is performed by irradiating the welding portion WD with the laser beams LASER. Therefore, in case that the welding process is performed on the welding portion WD, the reference voltage Vref from the reference line RL may be transmitted to the adjacent pixel plate pattern 121A in the same column through the bypass reference line RLa.

For example, the pair of first-first bypass data lines DL1a may include one first-first bypass data line DL1a extending from the right upper end corner of the bypass plate pattern 121B, and the remaining first-first bypass data line DL1a extending from the right lower end corner of the bypass plate pattern 121B. Further, the pair of first-second bypass data lines DL1b may include one first-second bypass data line DL1b extending from the right upper end corner of the bypass plate pattern 121B, and the remaining first-second bypass data line DL1b extending from the right lower end corner of the bypass plate pattern 121B.

Further, the welding portions WD may be respectively disposed between the first-first bypass data line DL1a extending from the right upper end corner of the bypass plate pattern 121B and the first-second bypass data line DL1b extending from the right lower end corner of the bypass plate pattern 121B, between the first-second bypass data line DL1b extending from the right upper end corner of the bypass plate pattern 121B and the first-first bypass data line DL1a extending from the right lower end corner of the bypass plate pattern 121B, and between the first-second bypass data line DL1b extending from the right upper end corner of the bypass plate pattern 121B and the first-second bypass data line DL1b extending from the right lower end corner of the bypass plate pattern 121B. Therefore, any one of the plurality of welding portions WD is selected, and the welding process is performed, such that the signal from the first data line DL1 may be transmitted to the adjacent pixel plate pattern 121A in the same column through the path from the first-first bypass data line DL1a to the first-first bypass data line DL1a and transmitted to the adjacent pixel plate pattern 121A in the same column through any one of the path from the first-first bypass data line DL1a to the first-second bypass data line DL1b and the path from the first-second bypass data line DL1b to the first-second bypass data line DL1b.

For example, the pair of second-first bypass data lines DL2a may include one second-first bypass data line DL2a extending from the left upper end corner of the bypass plate pattern 121B, and the remaining second-first bypass data line DL2a extending from the left lower end corner of the bypass plate pattern 121B. The pair of second-second bypass data lines DL2b may include one second-second bypass data line DL2b extending from the left upper end corner of the bypass plate pattern 121B, and the remaining second-second bypass data line DL2b extending from the left lower end corner of the bypass plate pattern 121B.

The welding portions WD may be respectively disposed between the second-first bypass data line DL2a extending from the left upper end corner of the bypass plate pattern 121B and the second-second bypass data line DL2b extending from the left lower end corner of the bypass plate pattern 121B, between the second-second bypass data line DL2b extending from the left upper end corner of the bypass plate pattern 121B and the second-first bypass data line DL2a extending from the left lower end corner of the bypass plate pattern 121B, and between the second-second bypass data line DL2b extending from the left upper end corner of the bypass plate pattern 121B and the second-second bypass data line DL2b extending from the left lower end corner of the bypass plate pattern 121B. Therefore, any one of the plurality of welding portions WD is selected, and the welding process is performed, such that the signal from the second data line DL2 may be transmitted to the adjacent pixel plate pattern 121A in the same column through the path from the second-first bypass data line DL2a to the second-first bypass data line DL2a and transmitted to the adjacent pixel plate pattern 121A in the same column through any one of the path from the second-first bypass data line DL2a to the second-second bypass data line DL2b and the path from the second-second bypass data line DL2b to the second-second bypass data line DL2b.

For example, the pair of third-first bypass data lines DL3a may include one third-first bypass data line DL3a extending from the left upper end corner of the bypass plate pattern 121B, and the remaining third-first bypass data line DL3a extending from the left lower end corner of the bypass plate pattern 121B. The pair of third-second bypass data lines DL3b may include one third-second bypass data line DL3b extending from the left upper end corner of the bypass plate pattern 121B, and the remaining third-second bypass data line DL3b extending from the left lower end corner of the bypass plate pattern 121B.

The welding portions WD may be respectively disposed between the third-first bypass data line DL3a extending from the left upper end corner of the bypass plate pattern 121B and the third-second bypass data line DL3b extending from the left lower end corner of the bypass plate pattern 121B, between the third-second bypass data line DL3b extending from the left upper end corner of the bypass plate pattern 121B and the third-first bypass data line DL3a extending from the left lower end corner of the bypass plate pattern 121B, and between the third-second bypass data line DL3b extending from the left upper end corner of the bypass plate pattern 121B and the third-second bypass data line DL3b extending from the left lower end corner of the bypass plate pattern 121B. Therefore, any one of the plurality of welding portions WD is selected, and the welding process is performed, such that the signal from the third data line DL3 may be transmitted to the adjacent pixel plate pattern 121A in the same column through the path from the third-first bypass data line DL3a to the third-first bypass data line DL3a and transmitted to the adjacent pixel plate pattern 121A in the same column through any one of the path from the third-first bypass data line DL3a to the third-second bypass data line DL3b and the path from the third-second bypass data line DL3b to the third-second bypass data line DL3b.

For example, the pair of bypass low-potential power lines VSSLa may include one bypass low-potential power line VSSLa extending toward the welding portion WD from the left lower end corner of the bypass plate pattern 121B, and the remaining bypass low-potential power line VSSLa extending toward the welding portion WD from the right lower end corner of the bypass plate pattern 121B. Further, the welding portion WD may be disposed between one bypass low-potential power line VSSLa and the remaining bypass low-potential power line VSSLa. Therefore, in case that the welding process is performed on the welding portion WD, the low-potential power voltage VSS from the low-potential power line VSSL may be transmitted to the adjacent pixel plate pattern 121A in the same row through the bypass low-potential power line VSSLa.

For example, the pair of first bypass scan lines SLa may include one first bypass scan line SLa extending from the left lower end corner of the bypass plate pattern 121B, and the remaining first bypass scan line SLa extending from the right lower end corner of the bypass plate pattern 121B. The pair of second bypass scan lines SLb may include one second bypass scan line SLb extending from the left lower end corner of the bypass plate pattern 121B, and the remaining second bypass scan line SLb extending from the right lower end corner of the bypass plate pattern 121B.

The welding portions WD may be respectively disposed between the first bypass scan line SLa extending from the left lower end corner of the bypass plate pattern 121B and the second bypass scan line SLb extending from the right lower end corner of the bypass plate pattern 121B, between the second bypass scan line SLb extending from the left lower end corner of the bypass plate pattern 121B and the first bypass scan line SLa extending from the right lower end corner of the bypass plate pattern 121B, and between the second bypass scan line SLb extending from the left lower end corner of the bypass plate pattern 121B and the second bypass scan line SLb extending from the right lower end corner of the bypass plate pattern 121B. Therefore, any one of the plurality of welding portions WD is selected, and the welding process is performed, such that the signal from the scan line SL may be transmitted to the adjacent pixel plate pattern 121A in the same row through the path from the first bypass scan line SLa to the second bypass scan line SLb and transmitted to the adjacent pixel plate pattern 121A in the same row through any one of the path from the second bypass scan line SLb to the first bypass scan line SLa and the path from the second bypass scan line SLb to the second bypass scan line SLb.

For example, the pair of first bypass light emission control lines EMLa may include one first bypass light emission control line EMLa extending from the left upper end corner of the bypass plate pattern 121B, and the remaining first bypass light emission control line EMLa extending from the right upper end corner of the bypass plate pattern 121B. The pair of second bypass light emission control lines EMLb may include one second bypass light emission control line EMLb extending from the left upper end corner of the bypass plate pattern 121B, and the remaining second bypass light emission control line EMLb extending from the right upper end corner of the bypass plate pattern 121B.

The welding portions WD may be respectively disposed between the first bypass light emission control line EMLa extending from the left upper end corner of the bypass plate pattern 121B and the second bypass light emission control line EMLb extending from the right upper end corner of the bypass plate pattern 121B, between the second bypass light emission control line EMLb extending from the left upper end corner of the bypass plate pattern 121B and the first bypass light emission control line EMLa extending from the right upper end corner of the bypass plate pattern 121B, and between the second bypass light emission control line EMLb extending from the left upper end corner of the bypass plate pattern 121B and the second bypass light emission control line EMLb extending from the right upper end corner of the bypass plate pattern 121B. Therefore, any one of the plurality of welding portions WD is selected, and the welding process is performed, such that the signal from the light emission control line EML may be transmitted to the adjacent pixel plate pattern 121A in the same row through the path from the first bypass light emission control line EMLa to the second bypass light emission control line EMLb and transmitted to the adjacent pixel plate pattern 121A in the same row through any one of the path from the second bypass light emission control line EMLb to the first bypass light emission control line EMLa and the path from the second bypass light emission control line EMLb to the second bypass light emission control line EMLb.

For example, the pair of bypass high-potential power lines VDDLa may include one bypass high-potential power line VDDLa extending toward the welding portion WD from the left upper end corner of the bypass plate pattern 121B, and the remaining bypass high-potential power line VDDLa extending toward the welding portion WD from the right upper end corner of the bypass plate pattern 121B. Further, the welding portion WD may be disposed between one bypass high-potential power line VDDLa and the remaining bypass high-potential power line VDDLa. Therefore, in case that the welding process is performed on the welding portion WD, the high-potential power voltage VDD from the high-potential power line VDDL may be transmitted to the adjacent pixel plate pattern 121A in the same row through the bypass high-potential power line VDDLa. In an example, the high-potential power voltage VDD is higher than the low-potential power voltage VSS. In an example, a magnitude of the high-potential power voltage VDD is greater than a magnitude of the low-potential power voltage VSS.

Next, with reference to FIGS. 8A to 9B, the welding portion WD may have various structures. The welding portion WD may include one or more metal layers that overlap ends of the pair of bypass lines. In the display device 100 according to the embodiment of the present disclosure, the welding portion WD may be formed by selecting any one of one embodiment of the welding portion WD including one metal layer and another embodiment of the welding portion WD including a plurality of metal layers.

With reference to FIG. 8A, one embodiment of the welding portion WD includes a first metal layer WDLa. For example, the second-first bypass data line DL2a and the second-second bypass data line DL2b may be disposed between the third interlayer insulation layer 146 and the passivation layer 147 and spaced apart from each other. The first metal layer WDLa of the welding portion WD may overlap an end of the second-first bypass data line DL2a and an end of the second-second bypass data line DL2b. Further, the first metal layer WDLa of the welding portion WD may be electrically connected to any one of the second-first bypass data line DL2a and the second-second bypass data line DL2b and disposed to be insulated from the other of the second-first bypass data line DL2a and the second-second bypass data line DL2b with the passivation layer 147 interposed therebetween. For example, the first metal layer WDLa may be disposed to be spaced apart from the end of the second-first bypass data line DL2a with the passivation layer 147 interposed therebetween, and the first metal layer WDLa may be electrically connected to the end of the second-second bypass data line DL2b through a contact hole of the passivation layer 147.

With reference to FIG. 8B, in case that a signal path is intended to be formed between the second-first bypass data line DL2a and the second-second bypass data line DL2b, the welding process may be performed by irradiating an area, in which the second-first bypass data line DL2a and the first metal layer WDLa overlap each other, with the laser beams LASER. Therefore, the passivation layer 147 between the second-first bypass data line DL2a and the first metal layer WDLa is partially removed by the laser beams LASER, and the first metal layer WDLa and the second-first bypass data line DL2a may be in contact with each other while being melted and then sintered. Therefore, the second-first bypass data line DL2a and the second-second bypass data line DL2b may be electrically connected to each other by the first metal layer WDLa during the welding process.

With reference to FIG. 9A, another embodiment of the welding portion WD includes the first metal layer WDLa and a second metal layer WDLb. The first metal layer WDLa may be electrically connected to the second-second bypass data line DL2b while overlapping the end of the second-second bypass data line DL2b. The second metal layer WDLb may be disposed between the second interlayer insulation layer 145 and the third interlayer insulation layer 146 and disposed to overlap the end of the second-first bypass data line DL2a and the end of the second-second bypass data line DL2b. The second metal layer WDLb may be electrically connected to the second-first bypass data line DL2a through a contact hole of the third interlayer insulation layer 146 and disposed to be insulated from the second-second bypass data line DL2b with the third interlayer insulation layer 146 interposed therebetween.

With reference to FIG. 9B, in case that the area, in which the first metal layer WDLa, the second metal layer WDLb, and the second-second bypass data line DL2b overlap one another, is irradiated with the laser beams LASER, the third interlayer insulation layer 146 may be partially removed, and the first metal layer WDLa, the second metal layer WDLb, and the second-second bypass data line DL2b may be electrically connected to one another. Therefore, the second-first bypass data line DL2a and the second-second bypass data line DL2b may be electrically connected to each other by the second metal layer WDLb during the welding process.

Next, with reference to FIG. 10, the plurality of third connection lines 183 may be disposed as multilayer structures on the plurality of first line patterns 122 to connect the plurality of bypass lines on the pixel plate pattern 121A and the bypass plate pattern 121B. For example, the plurality of third lower connection lines 183a and the plurality of third upper connection lines 183b may be disposed on one first line pattern 122.

For example, the plurality of third lower connection lines 183a, which connect the first bypass light emission control line EMLa, the second bypass light emission control line EMLb, and the bypass high-potential power line VDDLa may be disposed on the first line pattern 122 disposed in area (1) in FIG. 2, i.e., an area between the right lower end corner of the pixel plate pattern 121A and the left upper end corner of the bypass plate pattern 121B. Further, the third interlayer insulation layer 146 may be disposed on the plurality of third lower connection lines 183a, and the plurality of third upper connection lines 183b, which connect the second-first bypass data line DL2a, the second-second bypass data line DL2b, the third-first bypass data line DL3a, and the third-second bypass data line DL3b, may be disposed on the third interlayer insulation layer 146.

The plurality of third lower connection lines 183a, which connect the first bypass light emission control line EMLa, the second bypass light emission control line EMLb, and the bypass high-potential power line VDDLa may be disposed in area (2) in FIG. 2, i.e., on the first line pattern 122 between the left lower end corner of the pixel plate pattern 121A and the right upper end corner of the bypass plate pattern 121B. The third interlayer insulation layer 146 may be disposed on the plurality of third lower connection lines 183a, and the plurality of third upper connection lines 183b, which connect the first-first bypass data line DL1a, the first-second bypass data line DL1b, and the bypass reference line RLa, may be disposed on the third interlayer insulation layer 146.

The plurality of third lower connection lines 183a, which connect the first bypass scan line SLa, the second bypass scan line SLb, and the bypass low-potential power line VSSLa may be disposed in area (3), i.e., on the first line pattern 122 disposed between the right upper end corner of the pixel plate pattern 121A and the left lower end corner of the bypass plate pattern 121B. The third interlayer insulation layer 146 may be disposed on the plurality of third lower connection lines 183a, and the plurality of third upper connection lines 183b, which connect the second-first bypass data line DL2a, the second-second bypass data line DL2b, the third-first bypass data line DL3a, and the third-second bypass data line DL3b, may be disposed on the third interlayer insulation layer 146.

The plurality of third lower connection lines 183a, which connect the first bypass scan line SLa, the second bypass scan line SLb, and the bypass low-potential power line VSSLa, may be disposed in area (4), i.e., on the first line pattern 122 disposed between the left upper end corner of the pixel plate pattern 121A and the right lower end corner of the bypass plate pattern 121B. The third interlayer insulation layer 146 may be disposed on the plurality of third lower connection lines 183a, and the plurality of third upper connection lines 183b, which connect the first-first bypass data line DL1a, the first-second bypass data line DL1b, and the bypass reference line RLa, may be disposed on the third interlayer insulation layer 146.

Hereinafter, a method of forming the bypass signal path by using the third connection line 183 and the bypass plate pattern 121B when the defective subpixel XSPX occurs will be described.

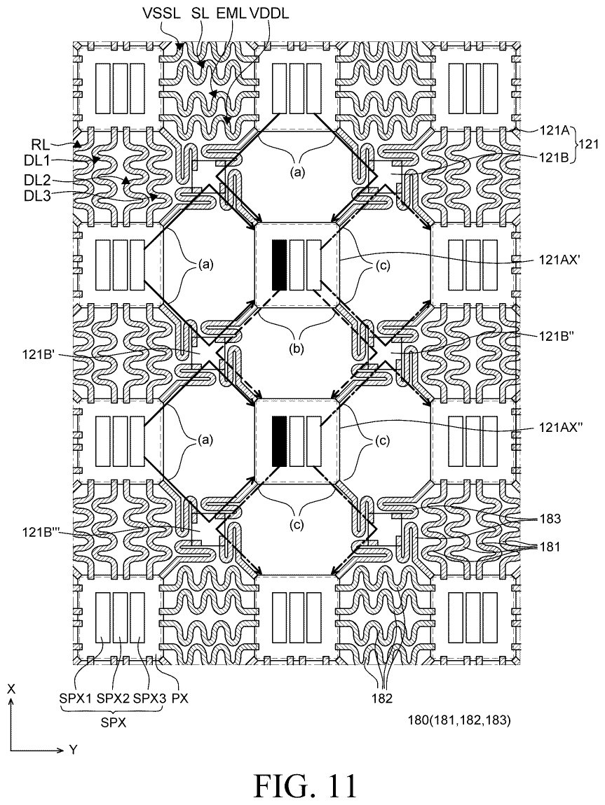

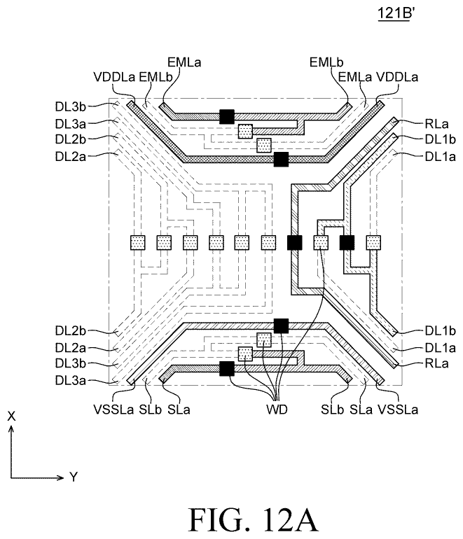

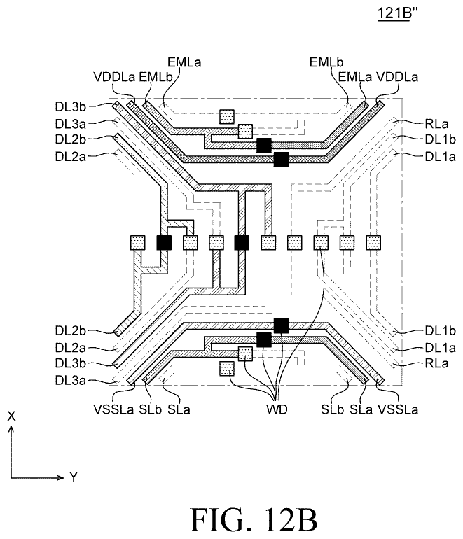

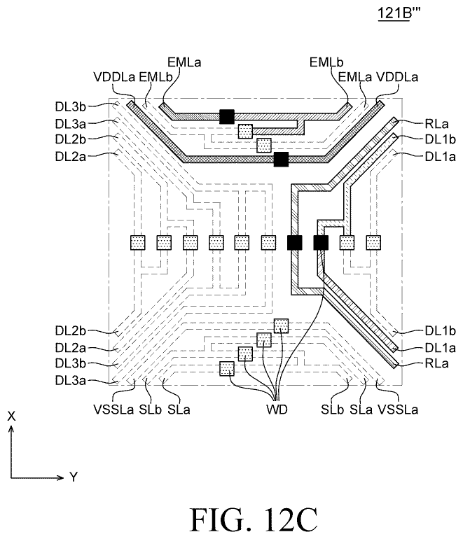

FIG. 11 is an enlarged top plan view of the display area of the display device according to the embodiment of the present disclosure. FIGS. 12A to 12C are enlarged top plan views of the plurality of bypass plate patterns of the display device according to the embodiment of the present disclosure. Specifically, FIG. 11 is a top plan view illustrating a state in which a line bypass process is completed when the defective subpixel XSPX occurs. FIG. 12A is an enlarged top plan view of a first bypass plate pattern 121B′ in FIG. 11, FIG. 12B is an enlarged top plan view of a second bypass plate pattern 121B″ in FIG. 11, and FIG. 12C is an enlarged top plan view of a third bypass plate pattern 121B″′ in FIG. 11. For convenience of description, in FIG. 11, path (a) is indicated by a thick solid line, path (b) is indicated by a dotted line, and path (c) is indicated by a one-dot chain line. Path (a), path (b), and path (c) may be referred to as the first path, second path, and third path, respectively. In addition, in FIGS. 12A to 12C, only the bypass lines on the signal transmission path are hatched, the bypass lines, to which no signal is transmitted, are indicated by dotted lines, without being hatched, and the welding portion WD, on which the welding process has been performed, is hatched in black.

With reference to FIG. 11, when defective pixel plate patterns 121AX′ and 121AX″, which include the defective subpixel XSPX among the plurality of pixel plate patterns 121A, are detected, the first connection line 181 and the second connection line 182 connected to the defective pixel plate patterns 121AX′ and 121AX″ may be removed. For example, the first connection line 181 and the second connection line 182 may be disconnected by at least partially removing the first connection line 181 and the second connection line 182 connected to the defective pixel plate patterns 121AX′ and 121AX″. The first connection line 181 and the second connection line 182 may be removed, and the first line patterns 122 having the first connection line 181 and the second connection line 182 may be removed, such that a signal to be transmitted to the line connected to the defective subpixel XSPX may be blocked, thereby suppressing a bright spot defect or the like of the defective subpixel XSPX.

Meanwhile, for convenience of description, FIG. 11 does not illustrate the first connection line 181 and the second connection line 182 between the defective pixel plate patterns 121AX′ and 121AX″ and a normal pixel plate pattern 121A. However, the first connection line 181 and the second connection line 182, which are actually disconnected, may be present on the lower substrate 111. However, the embodiments of the present disclosure are not limited thereto. For example, the first connection line 181 and the second connection line 182 are disconnected by being at least partially removed, such that erroneous operations of the defective pixel plate patterns 121AX′ and 121AX″ may be suppressed, and the remnant of the disconnected first and second connection lines 181 and 182 may remain on the lower substrate 111. Further, a portion of the first line pattern 122 disposed below the disconnected first and second connection lines 181 and 182 may be present on the lower substrate 111.

Hereinafter, the signal bypass method will be described on the assumption that the first pixel plate pattern 121AX′ and the second pixel plate pattern 121AX″, which is adjacent to the first pixel plate pattern 121AX′ in the first direction X, are respectively the defective pixel plate patterns 121AX′ and 121AX″ including the defective subpixel XSPX.

First, in case that the defective subpixel XSPX is formed on the first pixel plate pattern 121AX′ and the second pixel plate pattern 121AX″, the first connection line 181 and the second connection line 182 connected to the first pixel plate pattern 121AX′ and the second pixel plate pattern 121AX″ may be removed, and the first line patterns 122, which support the first connection line 181 and the second connection line 182, may be removed.

Next, the bypass line of the bypass plate pattern 121B may be connected, such that the signal may be transmitted to other pixel plate patterns 121A adjacent to the first pixel plate pattern 121AX′ and the second pixel plate pattern 121AX″. In this case, the signal bypass path may be configured as any one of paths (a), (b), and (c).

First, path (a) is a path through which the signal of the pixel plate pattern 121A including only the normal subpixel SPX is transmitted to the bypass lines on the first pixel plate pattern 121AX′ and the second pixel plate pattern 121AX″ including the defective subpixel XSPX. The signals, which have been previously transmitted to the adjacent pixel plate pattern 121A through the first connection line 181 and the second connection line 182, may be transmitted to the adjacent pixel plate pattern 121A through the third connection line 183 and the plurality of bypass lines on the pixel plate pattern 121A and the bypass plate pattern 121B. Therefore, path (a) may be a signal path passing through the bypass line on the pixel plate pattern 121A including the normal subpixel SPX, one of the third connection lines 183, the bypass line on the bypass plate pattern 121B, another one of the third connection lines 183, and the bypass lines on the first pixel plate pattern 121AX′ and the second pixel plate pattern 121AX″.

In this case, in order to suppress a bright spot defect in which a signal is transmitted to the defective subpixel XSPX and thus the defective subpixel XSPX emits light all the time regardless of an image, path (a) may preferentially use the second type bypass line among the plurality of bypass lines on the first pixel plate pattern 121AX′ and the second pixel plate pattern 121AX″. For example, the first type bypass line, which receives the signal directly from the existing line, may be used between the bypass plate pattern 121B and the pixel plate pattern 121A including the normal subpixel SPX, and the second type bypass line, which is separated from the existing line and the circuit of the subpixel SPX, may be preferentially used between the bypass plate pattern 121B and the first pixel plate pattern 121AX′. Therefore, the signal path is preferentially formed on the second type bypass line among the plurality of bypass lines on the first pixel plate pattern 121AX′ and the second pixel plate pattern 121AX″, thereby suppressing an operation of the defective subpixel XSPX.

However, some bypass lines may include only the first type bypass line, such that a path of a signal, such as the low-potential power voltage VSS, the high-potential power voltage VDD, and the reference voltage Vref, may be formed on the first type bypass line. However, the data voltage Vdata, the light emission control signal EM, the scan signal SCAN, and the like, which pass through the second type bypass line, are not applied to the defective subpixel XSPX, such that the defective subpixel XSPX cannot operate, thereby suppressing a bright spot defect.

Path (b) is a signal transmission path between the bypass line on the second pixel plate pattern 121AX″ and the bypass line on the first pixel plate pattern 121AX′ including the defective subpixel XSPX. For example, the first pixel plate pattern 121AX′ and the second pixel plate pattern 121AX″ may be disposed to be adjacent to each other in the first direction X. In this case, the signals of the lines extending in the first direction X, i.e., the data voltage Vdata and the reference voltage Vref may be transmitted to the normal pixel plate pattern 121A below the second pixel plate pattern 121AX″ via the bypass line on the first pixel plate pattern 121AX′ and the bypass line on the second pixel plate pattern 121AX″. Therefore, path (b) may be a signal path passing through the bypass line on the first pixel plate pattern 121AX′, one of the third connection lines 183, the bypass line on the bypass plate pattern 121B, another one of the third connection lines 183, and the bypass line on the second pixel plate pattern 121AX″.

In this case, path (b) may preferentially use the second type bypass line in order to suppress a bright spot defect in which the defective subpixel XSPX of the second pixel plate pattern 121AX″ emits light by a signal transmitted from the first pixel plate pattern 121AX′ to the second pixel plate pattern 121AX″. For example, the signal from the first pixel plate pattern 121AX′ may be transmitted to the second type bypass line on the second pixel plate pattern 121AX″. In case that a line for the signal includes only the first type bypass line among the plurality of bypass lines on the second pixel plate pattern 121AX″, the signal is transmitted to the first type bypass line. However, in case that a line for the signal includes both the first type bypass line and the second type bypass line, the signal may be transmitted to the second type bypass line. Therefore, the signal path is preferentially formed on the second type bypass line among the plurality of bypass lines on the second pixel plate pattern 121AX″, thereby suppressing an operation of the defective subpixel XSPX.

Path (c) is a path through which the signal is transmitted to the plurality of lines on the pixel plate pattern 121A including only the normal subpixel SPX from the plurality of bypass lines on the first pixel plate pattern 121AX′ and the second pixel plate pattern 121AX″ including the defective subpixel XSPX. The signals transmitted to the plurality of bypass lines on the first pixel plate pattern 121AX′ and the second pixel plate pattern 121AX″ through paths (a) and (b) may be transmitted to the adjacent pixel plate pattern 121A along the third connection line 183 on path (c) and the plurality of bypass lines on the bypass plate pattern 121B. Therefore, path (c) may be a signal path passing through the bypass line on the first pixel plate pattern 121AX′ and the second pixel plate pattern 121AX″ including the defective subpixel XSPX, one of the third connection lines 183, the bypass line on the bypass plate pattern 121B, another one of the third connection lines 183, and the bypass line and the plurality of lines on the pixel plate pattern 121A including only the normal subpixel SPX.

In this case, in order to transmit the signal to the plurality of lines on the pixel plate pattern 121A including the normal subpixel SPX, path (c) may transmit the signal to the first type bypass line among the plurality of bypass lines disposed on the pixel plate pattern 121A including the normal subpixel SPX. Because the first type bypass line, among the plurality of bypass lines, is connected directly to the plurality of lines, the signal may be transmitted to the plurality of lines by transmitting the signal to the first type bypass line. Therefore, the signal path may be formed by connecting the first type bypass line, among the plurality of bypass lines disposed on the pixel plate pattern 121A including the normal subpixel SPX, to the third connection line 183, thereby operating the normal subpixel SPX.

With reference to FIGS. 11 and 12A, the signal transmission paths of paths (a) and (b) may be formed on the first bypass plate pattern 121B′ disposed between a left lower end of the first pixel plate pattern 121AX′ and a left upper end of the second pixel plate pattern 121AX″.

For example, the light emission control signal EM and the high-potential power voltage VDD may be transmitted to path (a) between the first pixel plate pattern 121AX′ and the pixel plate pattern 121A disposed at a left side of the first pixel plate pattern 121AX′. Therefore, on the first bypass plate pattern 121B′, the welding process may be performed on the welding portion WD between the first bypass light emission control line EMLa and the second bypass light emission control line EMLb and the welding portion WD between the pair of bypass high-potential power lines VDDLa.

Therefore, the light emission control signal EM from the pixel plate pattern 121A disposed at the left side of the first pixel plate pattern 121AX′ may be transmitted to the second bypass light emission control line EMLb on the first pixel plate pattern 121AX′ through the third connection line 183 and the first bypass light emission control line EMLa and the second bypass light emission control line EMLb on the first bypass plate pattern 121B′. Further, the high-potential power voltage VDD from the pixel plate pattern 121A disposed at the left side of the first pixel plate pattern 121AX′ may be transmitted to the bypass high-potential power line VDDLa on the first pixel plate pattern 121AX′ through the third connection line 183 and the bypass high-potential power line VDDLa on the first bypass plate pattern 121B′. In this case, the second bypass light emission control line EMLb is separated from the circuit of the defective subpixel XSPX, thereby suppressing an operation of the defective subpixel XSPX.

For example, the low-potential power voltage VSS and the scan signal SCAN may be transmitted to path (a) between the second pixel plate pattern 121AX″ and the pixel plate pattern 121A disposed at the left side of the second pixel plate pattern 121AX″. Therefore, on the first bypass plate pattern 121B′, the welding process may be performed on the welding portion WD between the first bypass scan line SLa and the second bypass scan line SLb and the welding portion WD between the pair of bypass low-potential power lines VSSLa.

Therefore, the scan signal SCAN from the pixel plate pattern 121A disposed at the left side of the second pixel plate pattern 121AX″ may be transmitted to the second bypass scan line SLb on the second pixel plate pattern 121AX″ through the third connection line 183 and the first bypass scan line SLa and the second bypass scan line SLb on the first bypass plate pattern 121B′. Further, the low-potential power voltage VSS from the pixel plate pattern 121A disposed at the left side of the second pixel plate pattern 121AX″ may be transmitted to the bypass low-potential power line VSSLa on the second pixel plate pattern 121AX″ through the third connection line 183 and the bypass low-potential power line VSSLa on the first bypass plate pattern 121B′.

For example, the reference voltage Vref and the first data voltage may be transmitted to path (b) between the first pixel plate pattern 121AX′ and the second pixel plate pattern 121AX″. Therefore, on the first bypass plate pattern 121B′, the welding process may be performed on the welding portion WD between the pair of first-second bypass data lines DL1b and the welding portion WD between the pair of bypass reference lines RLa.

Therefore, the first data voltage from the first pixel plate pattern 121AX′ may be transmitted to the first-second bypass data line DL1b on the second pixel plate pattern 121AX″ through the third connection line 183 and the pair of first-second bypass data lines DL1b on the first bypass plate pattern 121B′. Further, the reference voltage Vref from the first pixel plate pattern 121AX′ may be transmitted to the bypass reference line RLa on the second pixel plate pattern 121AX″ through the third connection line 183 and the pair of bypass reference lines RLa on the first bypass plate pattern 121B′.

With reference to FIGS. 11 and 12B, the signal transmission paths of paths (b) and (c) may be formed on the second bypass plate pattern 121B″ disposed between a right lower end of the first pixel plate pattern 121AX′ and a right upper end of the second pixel plate pattern 121AX″.

For example, the light emission control signal EM and the high-potential power voltage VDD may be transmitted to path (c) between the first pixel plate pattern 121AX′ and the pixel plate pattern 121A disposed at a right side of the first pixel plate pattern 121AX′. Therefore, on the second bypass plate pattern 121B″, the welding process may be performed on the welding portion WD between the second bypass light emission control line EMLb and the first bypass light emission control line EMLa and the welding portion WD between the pair of bypass high-potential power lines VDDLa.

Therefore, the light emission control signal EM from the first pixel plate pattern 121AX′ may be transmitted to the first bypass light emission control line EMLa and the light emission control line EML on the pixel plate pattern 121A at the right side through the third connection line 183 and the second bypass light emission control line EMLb and the first bypass light emission control line EMLa on the second bypass plate pattern 121B″.

Further, the high-potential power voltage VDD from the first pixel plate pattern 121AX′ may be transmitted to the bypass high-potential power line VDDLa and the high-potential power line VDDL on the pixel plate pattern 121A disposed at the right side of the first pixel plate pattern 121AX′ through the third connection line 183 and the bypass high-potential power line VDDLa on the second bypass plate pattern 121B″. Therefore, the signal from the pixel plate pattern 121A disposed at the left side of the first pixel plate pattern 121AX′ may be transmitted to the pixel plate pattern 121A disposed at the right side of the first pixel plate pattern 121AX′ through paths (a) and (c).

For example, the low-potential power voltage VSS and the scan signal SCAN may be transmitted to path (c) between the second pixel plate pattern 121AX″ and the pixel plate pattern 121A disposed at the right side of the second pixel plate pattern 121AX″. Therefore, on the second bypass plate pattern 121B″, the welding process may be performed on the welding portion WD between the second bypass scan line SLb and the first bypass scan line SLa and the welding portion WD between the pair of bypass low-potential power lines VSSLa.

Therefore, the scan signal SCAN from the second pixel plate pattern 121AX″ may be transmitted to the first bypass scan line SLa and the scan line SL on the pixel plate pattern 121A at the right side of the second pixel plate pattern 121AX″ through the third connection line 183 and the second bypass scan line SLb and the first bypass scan line SLa on the second bypass plate pattern 121B″. Further, the low-potential power voltage VSS from the second pixel plate pattern 121AX″ may be transmitted to the bypass low-potential power line VSSLa and the low-potential power line VSSL on the pixel plate pattern 121A at the right side of the second pixel plate pattern 121AX″ through the third connection line 183 and the bypass low-potential power line VSSLa on the second bypass plate pattern 121B″.

For example, the second data voltage and the third data voltage may be transmitted to path (b) between the first pixel plate pattern 121AX′ and the second pixel plate pattern 121AX″. Therefore, on the second bypass plate pattern 121B″, the welding process may be performed on the welding portion WD between the pair of second-second bypass data lines DL2b and the welding portion WD between the pair of third-second bypass data lines DL3b.

Therefore, the second data voltage from the first pixel plate pattern 121AX′ may be transmitted to the second-second bypass data line DL2b on the second pixel plate pattern 121AX″ through the third connection line 183 and the pair of second-second bypass data lines DL2b on the second bypass plate pattern 121B″. Further, the third data voltage from the first pixel plate pattern 121AX′ may be transmitted to the third-second bypass data line DL3b on the second pixel plate pattern 121AX″ through the third connection line 183 and the pair of third-second bypass data lines DL3b on the second bypass plate pattern 121B″.

With reference to FIGS. 11 and 12C, signal transmission paths of paths (a) and (c) may be formed on the third bypass plate pattern 121B″′ adjacent to a left lower end of the second pixel plate pattern 121AX″.

For example, the light emission control signal EM and the high-potential power voltage VDD may be transmitted to path (a) between the second pixel plate pattern 121AX″ and the pixel plate pattern 121A disposed at the left side of the second pixel plate pattern 121AX″. Therefore, on the third bypass plate pattern 121B″′, the welding process may be performed on the welding portion WD between the first bypass light emission control line EMLa and the second bypass light emission control line EMLb and the welding portion WD between the pair of bypass high-potential power lines VDDLa.

Therefore, the light emission control signal EM from the pixel plate pattern 121A disposed at the left side of the second pixel plate pattern 121AX″ may be transmitted to the second bypass light emission control line EMLb on the second pixel plate pattern 121AX″ through the third connection line 183 and the first bypass light emission control line EMLa and the second bypass light emission control line EMLb on the third bypass plate pattern 121B″′. Further, the high-potential power voltage VDD from the pixel plate pattern 121A disposed at the left side of the second pixel plate pattern 121AX″ may be transmitted to the bypass high-potential power line VDDLa on the second pixel plate pattern 121AX″ through the third connection line 183 and the bypass high-potential power line VDDLa on the third bypass plate pattern 121B″′.

For example, the reference voltage Vref and the first data voltage may be transmitted to path (c) between the second pixel plate pattern 121AX″ and the pixel plate pattern 121A below the second pixel plate pattern 121AX′. Therefore, on the third bypass plate pattern 121B″′, the welding process may be performed on the welding portion WD between the first-second bypass data line DL1b and the first-first bypass data line DL1a and the welding portion WD between the pair of bypass reference lines RLa.

Therefore, the first data voltage from the second pixel plate pattern 121AX″ may be transmitted to the first-first bypass data line DL1a and the first data line DL1 on the pixel plate pattern 121A below the second pixel plate pattern 121AX″ through the third connection line 183 and the first-second bypass data line DL1b and the first-first bypass data line DL1a on the third bypass plate pattern 121B″′. Further, the reference voltage Vref from the second pixel plate pattern 121AX″ may be transmitted to the bypass reference line RLa and the reference line RL on the pixel plate pattern 121A below the second pixel plate pattern 121AX″ through the third connection line 183 and the pair of bypass reference lines RLa on the third bypass plate pattern 121B″′.

Therefore, in the display device 100 according to the embodiment of the present disclosure, the signal may be transmitted to the normal subpixel SPX by using the plurality of bypass plate patterns 121B and the plurality of bypass lines. For example, both the first connection line 181 and the second connection line 182 connected to the pixel plate pattern 121A having the defective subpixel XSPX may be removed, thereby suppressing a bright spot defect of the defective subpixel XSPX. In this case, various types of signals transmitted to the adjacent pixel plate pattern 121A through the existing first and second connection lines 181 and 182 may be transmitted to the pixel plate patterns 121A in the same row or the same column through the plurality of bypass lines and the plurality of third connection lines 183 on the pixel plate pattern 121A and the bypass plate pattern 121B. Therefore, the signal may be transmitted to the remaining pixel plate pattern 121A by using the bypass line even though the first connection line 181 and the second connection line 182 connected to the pixel plate pattern 121A having the defective subpixel XSPX are removed.

In addition, the display device 100 according to the embodiment of the present disclosure may include the second type bypass line separated from the plurality of lines and the circuit of the subpixel SPX, thereby inhibiting the signal from being applied to the defective subpixel XSPX. The first type bypass line may be connected directly to the plurality of lines and receive the signal. In case that the signal is transmitted to the first type bypass line among the plurality of bypass lines on the pixel plate pattern 121A having the defective subpixel XSPX, the defective subpixel XSPX may abnormally operate by receiving the signal through the first type bypass line and the line connected to the first type bypass line. Therefore, the bypass signal path may be preferentially formed on the second type bypass line on the pixel plate pattern 121A having the defective subpixel XSPX, thereby suppressing an abnormal operation of the defective subpixel XSPX.

Various examples and aspects of the present disclosure are described below. These are provided as examples, and do not limit the scope of the present disclosure.

According to one or more aspects of the present disclosure, a display device includes a substrate, a pattern layer disposed on the substrate and comprising a plurality of pixel plate patterns, a plurality of bypass plate patterns, and a plurality of first line patterns, a plurality of subpixels disposed on the plurality of pixel plate patterns, each of the plurality of subpixels comprising a circuit and a light-emitting element configured to be operated by the circuit, a plurality of lines disposed on the plurality of pixel plate patterns and connected to the circuits, respectively, a plurality of bypass lines disposed on the plurality of pixel plate patterns and the plurality of bypass plate patterns, respectively, and a plurality of connection lines disposed on the plurality of first line patterns, respectively.

The plurality of first line patterns is disposed between at least some of the plurality of pixel plate patterns and between the plurality of pixel plate patterns and the plurality of bypass plate patterns, respectively. Some of the plurality of lines on some of the plurality of pixel plate patterns are configured to receive signals from corresponding lines of the plurality of lines on one or more adjacent pixel plate patterns. Some of the plurality of lines on some of remaining pixel plate patterns are configured to receive signals from corresponding bypass lines of the plurality of bypass lines on some of the plurality of bypass plate patterns. The plurality of pixel plate patterns include the some of the plurality of pixel plate patterns and the remaining pixel plate patterns.

The plurality of connection lines may include a plurality of first connection lines extending in a first direction and connected to the plurality of lines on the plurality of pixel plate patterns, respectively, a plurality of second connection lines extending in a second direction different from the first direction and connected to the plurality of lines on the plurality of pixel plate patterns, respectively, and a plurality of third connection lines extending in a direction different from the first direction and the second direction and connected to the plurality of bypass lines on the plurality of pixel plate patterns and the plurality of bypass lines on the plurality of bypass plate patterns, respectively.

The plurality of bypass lines may include first type bypass lines electrically connected to the plurality of lines, respectively, and second type bypass lines separated from the plurality of lines and the circuits of the plurality of subpixels. Some of the first type bypass lines on the plurality of pixel plate patterns may be connected to corresponding bypass lines of the first type bypass lines on the plurality of bypass plate patterns through corresponding third connection lines. One or more first type bypass lines on a bypass plate pattern may be disposed at two opposite sides of each of the plurality of pixel plate patterns. Some of the second type bypass lines on the plurality of pixel plate patterns may be connected to corresponding bypass lines of the second type bypass lines on the plurality of bypass plate patterns through corresponding third connection lines. One or more second type bypass lines on a bypass plate pattern may be disposed at two opposite sides of each of the plurality of pixel plate patterns. On each of the plurality of bypass plate patterns, a pair of first type bypass lines connected to corresponding first type bypass lines of different pixel plate patterns may be disposed to be spaced apart from each other, and a pair of second type bypass lines connected to corresponding second type bypass lines of different pixel plate patterns may be disposed to be spaced apart from each other.

The display device may further include a plurality of welding portions disposed respectively on the plurality of bypass plate patterns and disposed respectively between any one of the pair of first type bypass lines and any one of the pair of second type bypass lines and between the pair of second type bypass lines. At least some of the plurality of bypass lines may be electrically connected to one another by corresponding welding portions of the plurality of welding portions.

The plurality of lines may include a reference line extending in the first direction and electrically connected to a respective one of the plurality of first connection lines, a first data line extending in the first direction and electrically connected to a respective one of the plurality of first connection lines, a second data line extending in the first direction and electrically connected to a respective one of the plurality of first connection lines, a third data line extending in the first direction and electrically connected to a respective one of the plurality of first connection lines, a low-potential power line extending in the second direction and electrically connected to a respective one of the plurality of second connection lines, a scan line extending in the second direction and electrically connected to a respective one of the plurality of second connection lines, a light emission control line extending in the second direction and electrically connected to a respective one of the plurality of second connection lines, and a high-potential power line extending in the second direction and electrically connected to a respective one of the plurality of second connection lines.

The plurality of bypass lines may include a bypass reference line electrically connected to the reference line, a bypass low-potential power line electrically connected to the low-potential power line, and a bypass high-potential power line electrically connected to the high-potential power line. The first type bypass lines may include the bypass reference line, the bypass low-potential power line, and the bypass high-potential power line.

The plurality of bypass lines may include a first-first bypass data line electrically connected to the first data line, a first-second bypass data line separated from the first data line, a second-first bypass data line electrically connected to the second data line, a second-second bypass data line separated from the second data line, a third-first bypass data line electrically connected to the third data line, a third-second bypass data line separated from the third data line, a first bypass scan line electrically connected to the scan line, a second bypass scan line separated from the scan line, a first bypass light emission control line electrically connected to the light emission control line, and a second bypass light emission control line separated from the light emission control line. The first type bypass lines may include the first-first bypass data line, the second-first bypass data line, the third-first bypass data line, the first bypass scan line, and the first bypass light emission control line, and the second type bypass lines may include the first-second bypass data line, the second-second bypass data line, the third-second bypass data line, the second bypass scan line, and the second bypass light emission control line.

A defective pixel plate pattern, which has a defective subpixel among the plurality of pixel plate patterns, may be separated from a respective first connection line and a respective second connection line and connected to a respective third connection line.

A signal from a line of the plurality of lines on a pixel plate pattern at one side of the defective pixel plate pattern may be transmitted along a first path to a respective bypass line of the plurality of bypass lines on the defective pixel plate pattern.

The first path may be a path passing through a respective first type bypass line on the pixel plate pattern at the one side, a first respective one of the plurality of third connection lines, one of the plurality of bypass lines on a first bypass plate pattern between the defective pixel plate pattern and the pixel plate pattern at the one side, a second respective one of the plurality of third connection lines, and the respective bypass line of the plurality of bypass lines on the defective pixel plate pattern. The respective bypass line of the plurality of bypass lines may include one or more of the bypass reference line, the bypass low-potential power line, the bypass high-potential power line, the first-second bypass data line, the second-second bypass data line, the third-second bypass data line, the second bypass scan line, and the second bypass light emission control line.

A signal transmitted to the respective bypass line of the plurality of bypass lines on the defective pixel plate pattern along the first path may be transmitted along a third path to one of the plurality of lines on a pixel plate pattern at another side of the defective pixel plate pattern.

The third path may be a path passing through a third respective one of the plurality of third connection lines, a bypass line of the plurality of bypass lines on a second bypass plate pattern between the defective pixel plate pattern and the pixel plate pattern at the another side, a fourth respective one of the plurality of third connection lines, and a first type bypass line and one of the plurality of lines on the pixel plate pattern at the another side.

The defective pixel plate pattern may include a first pixel plate pattern. A second pixel plate pattern may be adjacent to the first pixel plate pattern, and the second pixel plate pattern may be another defective pixel plate pattern. A signal transmitted to a bypass line of the plurality of bypass lines on the first pixel plate pattern may be transmitted along a second path to a bypass line of the plurality of bypass lines on the second pixel plate pattern.

The second path may be a path passing through a fifth respective one of the plurality of third connection lines, a bypass line of the plurality of bypass lines on a third bypass plate pattern between the first pixel plate pattern and the second pixel plate pattern, a sixth respective one of the plurality of third connection lines, and the bypass line of the plurality of bypass lines on the second pixel plate pattern.

Each of the first, second and third paths may pass through a pair of bypass lines among the plurality of bypass lines on a respective one of the plurality of bypass plate patterns, and the pair of bypass lines may be electrically connected to each other by a welding portion.

According to one or more aspects of the present disclosure, a display device includes a substrate; a pattern layer disposed on the substrate and comprising a plurality of pixel plate patterns, a plurality of bypass plate patterns, and a plurality of first line patterns; a plurality of subpixels disposed on the plurality of pixel plate patterns, each of the plurality of subpixels comprising a circuit and a light-emitting element configured to be operated by the circuit; a plurality of lines disposed on the plurality of pixel plate patterns and connected to the circuits, respectively; a plurality of bypass lines disposed on the plurality of pixel plate patterns and the plurality of bypass plate patterns, respectively; and a plurality of connection lines disposed on the plurality of first line patterns, respectively. The plurality of first line patterns may be disposed between the plurality of pixel plate patterns and between the plurality of pixel plate patterns and the plurality of bypass plate patterns, respectively.

The plurality of lines may include a reference line extending in a first direction, a first data line extending in the first direction, a second data line extending in the first direction, and a third data line extending in the first direction. The plurality of bypass lines may include a bypass reference line connected to the reference line on a pixel plate pattern, a first-first bypass data line connected to the first data line on the pixel plate pattern, a second-first bypass data line connected to the second data line on the pixel plate pattern, and a third-first bypass data line connected to the third data line on the pixel plate pattern, and one end of each of the bypass reference line, the first-first bypass data line, the second-first bypass data line, and the third-first bypass data line may extend to any one of a left upper end corner and a right upper end corner of the pixel plate pattern, and the other end of each of the bypass reference line, the first-first bypass data line, the second-first bypass data line, and the third-first bypass data line may extend to any one of a left lower end corner and a right lower end corner of the pixel plate pattern.

The plurality of bypass lines may further include a first-second bypass data line disposed on the pixel plate pattern and spaced apart from the first data line, a second-second bypass data line disposed on the pixel plate pattern and spaced apart from the second data line, and a third-second bypass data line disposed on the pixel plate pattern and spaced apart from the third data line, and one end of each of the first-second bypass data line, the second-second bypass data line, and the third-second bypass data line may extend to any one of the left upper end corner and the right upper end corner of the pixel plate pattern, and the other end of each of the first-second bypass data line, the second-second bypass data line, and the third-second bypass data line may extend to any one of the left lower end corner and the right lower end corner of the pixel plate pattern.

The plurality of lines may further include a low-potential power line extending in a second direction, a scan line extending in the second direction, a light emission control line extending in the second direction, and a high-potential power line extending in the second direction, and the plurality of bypass lines may further include a bypass low-potential power line connected to the low-potential power line on the pixel plate pattern, a first bypass scan line connected to the scan line on the pixel plate pattern, a first bypass light emission control line connected to the light emission control line on the pixel plate pattern, and a bypass high-potential power line connected to the high-potential power line on the pixel plate pattern. One end of each of the bypass low-potential power line, the first bypass scan line, the first bypass light emission control line, and the bypass high-potential power line may extend to any one of the left upper end corner and the left lower end corner of the pixel plate pattern, and the other end of each of the bypass low-potential power line, the first bypass scan line, the first bypass light emission control line, and the bypass high-potential power line may extend to any one of the right upper end corner and the right lower end corner of the pixel plate pattern.

The plurality of bypass lines may further include a second bypass scan line disposed on the pixel plate pattern and spaced apart from the scan line, and a second bypass light emission control line disposed on the pixel plate pattern and spaced apart from the light emission control line, and one end of each of the second bypass scan line and the second bypass light emission control line may extend to any one of the left upper end corner and the left lower end corner of the pixel plate pattern, and the other end of each of the second bypass scan line and the second bypass light emission control line may extend to any one of the right upper end corner and the right lower end corner of the pixel plate pattern.

On each bypass plate pattern of the plurality of bypass plate patterns, one end of each of the bypass reference line, the first-first bypass data line, the second-first bypass data line, the third-first bypass data line, the first-second bypass data line, the second-second bypass data line, and the third-second bypass data line may extend to any one of a left upper end corner and a right upper end corner of the respective bypass plate pattern, and the other end of each of the bypass reference line, the first-first bypass data line, the second-first bypass data line, the third-first bypass data line, the first-second bypass data line, the second-second bypass data line, and the third-second bypass data line may extend to any one of a left lower end corner and a right lower end corner of the respective bypass plate pattern. On each bypass plate pattern of the plurality of bypass plate patterns, one end of each of the bypass low-potential power line, the first bypass scan line, the first bypass light emission control line, the bypass high-potential power line, the second bypass scan line, and the second bypass light emission control line may extend to any one of the left upper end corner and the left lower end corner of the respective bypass plate pattern, and the other end of each of the bypass low-potential power line, the first bypass scan line, the first bypass light emission control line, the bypass high-potential power line, the second bypass scan line, and the second bypass light emission control line may extend to any one of the right upper end corner and the right lower end corner of the respective bypass plate pattern.

Two bypass lines, among the plurality of bypass lines, may be disposed on each of the plurality of bypass plate patterns, and the display device may further include a plurality of welding portions disposed on the plurality of bypass plate patterns and disposed between the plurality of bypass lines.

Among the plurality of welding portions, at least one welding portion may be disposed between a pair of bypass reference lines, at least one welding portion may be disposed between a pair of first-first bypass data lines, at least one welding portion may be disposed between a pair of second-first bypass data lines, at least one welding portion may be disposed between a pair of third-first bypass data lines, at least one welding portion may be disposed between the first-first bypass data line and the first-second bypass data line, at least one welding portion may be disposed between the second-first bypass data line and the second-second bypass data line, at least one welding portion may be disposed between the third-first bypass data line and the third-second bypass data line, at least one welding portion may be disposed between a pair of bypass low-potential power lines, at least one welding portion may be disposed between a pair of first bypass scan lines, at least one welding portion may be disposed between a pair of first bypass light emission control lines, at least one welding portion may be disposed between a pair of bypass high-potential power lines, at least one welding portion may be disposed between the first bypass scan line and the second bypass scan line, and at least one welding portion may be disposed between the first bypass light emission control line and the second bypass light emission control line.

According to one or more aspects of the present disclosure, a display device includes a plurality of pixel plate patterns, a plurality of bypass plate patterns, a plurality of subpixels disposed on the plurality of pixel plate patterns, each of the plurality of subpixels comprising a light-emitting element, a plurality of lines disposed on the plurality of pixel plate patterns, respectively, a plurality of bypass lines disposed on the plurality of pixel plate patterns and the plurality of bypass plate patterns, respectively, and a plurality of connection lines.

A first subset of the plurality of connection lines may be disposed between adjacent ones of the plurality of pixel plate patterns. A second set of the plurality of connection lines may be disposed between the plurality of pixel plate patterns and the plurality of bypass plate patterns.

The plurality of pixel plate patterns may form islands that are separate from one another.

The plurality of bypass plate patterns may form islands that are separate from one another and separate from the plurality of pixel plate patterns.

Each of the plurality of pixel plate patterns may be larger than any bypass plate pattern that is adjacent to a corresponding pixel plate pattern.

One or more transistors may be disposed on each of the plurality of pixel plate patterns.

No transistor is disposed on any of the plurality of bypass plate patterns.

No light-emitting element is disposed on any of the plurality of bypass plate patterns.

The plurality of lines on the plurality of pixel plate patterns may extend straight in a first direction or a second direction perpendicular to the first direction.

The plurality of bypass lines disposed on the plurality of pixel plate patterns may extend in a direction oblique to both the first and second directions.

The plurality of bypass lines disposed on the plurality of bypass plate patterns may extend straight in the first direction or the second direction and may extend in a direction oblique to both the first and second directions.

The plurality of bypass lines may include first type bypass lines and second type bypass lines. Within the plurality of pixel plate patterns, the first type bypass lines on the plurality of pixel plate patterns may be connected directly to the plurality of lines on the plurality of pixel plate patterns. Within the plurality of pixel plate patterns, the second type bypass lines on the plurality of pixel plate patterns are not connected to the plurality of lines on the plurality of pixel plate patterns and are not connected the first type bypass lines on the plurality of pixel plate patterns.

A second type bypass line on a bypass plate pattern may prevent a signal from being transmitted to a defective subpixel on a pixel plate pattern.

The light-emitting elements, which may be provided individually or as an array, may be manufactured on a separate base substrate. Subsequently, the light-emitting elements may be inverted and positioned on the bonding layer with the individual light-emitting elements inserted or deposited into corresponding openings defined in the bank.

The display device further include a substrate. The plurality of pixel plate patterns and a plurality of bypass plate patterns are disposed on the substrate and are more rigid than the substrate.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a pattern layer disposed on the substrate and comprising a plurality of pixel plate patterns, a plurality of bypass plate patterns, and a plurality of first line patterns;
a plurality of subpixels disposed on the plurality of pixel plate patterns, each of the plurality of subpixels comprising a circuit and a light-emitting element configured to be operated by the circuit;
a plurality of lines disposed on the plurality of pixel plate patterns and connected to the circuits, respectively;
a plurality of bypass lines disposed on the plurality of pixel plate patterns and the plurality of bypass plate patterns, respectively; and
a plurality of connection lines disposed on the plurality of first line patterns, respectively,
wherein the plurality of first line patterns is disposed between at least some of the plurality of pixel plate patterns and between the plurality of pixel plate patterns and the plurality of bypass plate patterns, respectively,
wherein some of the plurality of lines on some of the plurality of pixel plate patterns are configured to receive signals from corresponding lines of the plurality of lines on one or more adjacent pixel plate patterns,
wherein some of the plurality of lines on some of remaining pixel plate patterns are configured to receive signals from corresponding bypass lines of the plurality of bypass lines on some of the plurality of bypass plate patterns, and
wherein the plurality of pixel plate patterns include the some of the plurality of pixel plate patterns and the remaining pixel plate patterns.

2. The display device of claim 1, wherein the plurality of connection lines comprises:
a plurality of first connection lines extending in a first direction and connected to the plurality of lines on the plurality of pixel plate patterns, respectively;
a plurality of second connection lines extending in a second direction different from the first direction and connected to the plurality of lines on the plurality of pixel plate patterns, respectively; and
a plurality of third connection lines extending in a direction different from the first direction and the second direction and connected to the plurality of bypass lines on the plurality of pixel plate patterns and the plurality of bypass lines on the plurality of bypass plate patterns, respectively.

3. The display device of claim 2, wherein the plurality of bypass lines comprises:
first type bypass lines electrically connected to the plurality of lines, respectively; and
second type bypass lines separated from the plurality of lines and the circuits of the plurality of subpixels,
wherein some of the first type bypass lines on the plurality of pixel plate patterns are connected to corresponding bypass lines of the first type bypass lines on the plurality of bypass plate patterns through corresponding third connection lines, wherein one or more first type bypass lines on a bypass plate pattern are disposed at two opposite sides of each of the plurality of pixel plate patterns,
wherein some of the second type bypass lines on the plurality of pixel plate patterns are connected to corresponding bypass lines of the second type bypass lines on the plurality of bypass plate patterns through corresponding third connection lines, wherein one or more second type bypass lines on a bypass plate pattern are disposed at two opposite sides of each of the plurality of pixel plate patterns, and
wherein on each of the plurality of bypass plate patterns, a pair of first type bypass lines connected to corresponding first type bypass lines of different pixel plate patterns are disposed to be spaced apart from each other, and a pair of second type bypass lines connected to corresponding second type bypass lines of different pixel plate patterns are disposed to be spaced apart from each other.

4. The display device of claim 3, further comprising:
a plurality of welding portions disposed respectively on the plurality of bypass plate patterns and disposed respectively between any one of the pair of first type bypass lines and any one of the pair of second type bypass lines and between the pair of second type bypass lines,
wherein at least some of the plurality of bypass lines are electrically connected to one another by corresponding welding portions of the plurality of welding portions.

5. The display device of claim 4, wherein the plurality of lines comprises:
a reference line extending in the first direction and electrically connected to a respective one of the plurality of first connection lines;
a first data line extending in the first direction and electrically connected to a respective one of the plurality of first connection lines;
a second data line extending in the first direction and electrically connected to a respective one of the plurality of first connection lines;
a third data line extending in the first direction and electrically connected to a respective one of the plurality of first connection lines;
a low-potential power line extending in the second direction and electrically connected to a respective one of the plurality of second connection lines;
a scan line extending in the second direction and electrically connected to a respective one of the plurality of second connection lines;
a light emission control line extending in the second direction and electrically connected to a respective one of the plurality of second connection lines; and
a high-potential power line extending in the second direction and electrically connected to a respective one of the plurality of second connection lines.

6. The display device of claim 5, wherein the plurality of bypass lines comprises:
a bypass reference line electrically connected to the reference line;
a bypass low-potential power line electrically connected to the low-potential power line; and
a bypass high-potential power line electrically connected to the high-potential power line, and
wherein the first type bypass lines comprise the bypass reference line, the bypass low-potential power line, and the bypass high-potential power line.

7. The display device of claim 6, wherein the plurality of bypass lines comprises:
a first-first bypass data line electrically connected to the first data line;
a first-second bypass data line separated from the first data line;
a second-first bypass data line electrically connected to the second data line;
a second-second bypass data line separated from the second data line;
a third-first bypass data line electrically connected to the third data line;
a third-second bypass data line separated from the third data line;
a first bypass scan line electrically connected to the scan line;
a second bypass scan line separated from the scan line;
a first bypass light emission control line electrically connected to the light emission control line; and
a second bypass light emission control line separated from the light emission control line,
wherein the first type bypass lines comprise the first-first bypass data line, the second-first bypass data line, the third-first bypass data line, the first bypass scan line, and the first bypass light emission control line, and
wherein the second type bypass lines comprise the first-second bypass data line, the second-second bypass data line, the third-second bypass data line, the second bypass scan line, and the second bypass light emission control line.

8. The display device of claim 7, wherein a defective pixel plate pattern, which has a defective subpixel among the plurality of pixel plate patterns, is separated from a respective first connection line and a respective second connection line and is connected to a respective third connection line.

9. The display device of claim 8, wherein a signal from a line of the plurality of lines on a pixel plate pattern at one side of the defective pixel plate pattern is being transmitted along a first path to a respective bypass line of the plurality of bypass lines on the defective pixel plate pattern.

10. The display device of claim 9, wherein the first path comprises a path passing through a respective first type bypass line on the pixel plate pattern at the one side, a first respective one of the plurality of third connection lines, one of the plurality of bypass lines on a first bypass plate pattern between the defective pixel plate pattern and the pixel plate pattern at the one side, a second respective one of the plurality of third connection lines, and the respective bypass line of the plurality of bypass lines on the defective pixel plate pattern, and
wherein the respective bypass line of the plurality of bypass lines comprises one or more of the bypass reference line, the bypass low-potential power line, the bypass high-potential power line, the first-second bypass data line, the second-second bypass data line, the third-second bypass data line, the second bypass scan line, and the second bypass light emission control line.

11. The display device of claim 10, wherein a signal transmitted to the respective bypass line of the plurality of bypass lines on the defective pixel plate pattern along the first path is transmitted along a third path to one of the plurality of lines on a pixel plate pattern at another side of the defective pixel plate pattern.

12. The display device of claim 11, wherein the third path is a path passing through a third respective one of the plurality of third connection lines, a bypass line of the plurality of bypass lines on a second bypass plate pattern between the defective pixel plate pattern and the pixel plate pattern at the another side, a fourth respective one of the plurality of third connection lines, and a first type bypass line and one of the plurality of lines on the pixel plate pattern at the another side.

13. The display device of claim 12, wherein the defective pixel plate pattern comprises a first pixel plate pattern,
wherein a second pixel plate pattern is adjacent to the first pixel plate pattern, and the second pixel plate pattern is another defective pixel plate pattern, and
wherein a signal transmitted to a bypass line of the plurality of bypass lines on the first pixel plate pattern is transmitted along a second path to a bypass line of the plurality of bypass lines on the second pixel plate pattern.

14. The display device of claim 13, wherein the second path is a path passing through a fifth respective one of the plurality of the third connection lines, a bypass line of the plurality of bypass lines on a third bypass plate pattern between the first pixel plate pattern and the second pixel plate pattern, a sixth respective one of the plurality of third connection lines, and the bypass line of the plurality of bypass lines on the second pixel plate pattern.

15. The display device of claim 14, wherein each of the first, second and third paths passes through a pair of bypass lines among the plurality of bypass lines on a respective one of the plurality of bypass plate patterns, and
wherein the pair of bypass lines are electrically connected to each other by a welding portion.

16. The display device of claim 2, wherein the plurality of third connection lines extends in a direction oblique to both the first and second directions.

17. The display device of claim 2, wherein each of the plurality of third connection lines includes a third upper connection line and a third lower connection line.

18. The display device of claim 17, wherein a third connection line extends to a corner of a bypass plate pattern adjacent to one of four corners of a pixel plate pattern.

19. A display device, comprising:
a substrate;
a pattern layer disposed on the substrate and comprising a plurality of pixel plate patterns, a plurality of bypass plate patterns, and a plurality of first line patterns;
a plurality of subpixels disposed on the plurality of pixel plate patterns, each of the plurality of subpixels comprising a circuit and a light-emitting element configured to be operated by the circuit;
a plurality of lines disposed on the plurality of pixel plate patterns and connected to the circuits, respectively;
a plurality of bypass lines disposed on the plurality of pixel plate patterns and the plurality of bypass plate patterns, respectively; and
a plurality of connection lines disposed on the plurality of first line patterns, respectively,
wherein the plurality of first line patterns is disposed between the plurality of pixel plate patterns and between the plurality of pixel plate patterns and the plurality of bypass plate patterns, respectively.

20. The display device of claim 19, wherein the plurality of lines comprises:
a reference line extending in a first direction;
a first data line extending in the first direction;
a second data line extending in the first direction; and
a third data line extending in the first direction,
wherein the plurality of bypass lines comprises:
a bypass reference line connected to the reference line on a pixel plate pattern;
a first-first bypass data line connected to the first data line on the pixel plate pattern;
a second-first bypass data line connected to the second data line on the pixel plate pattern; and
a third-first bypass data line connected to the third data line on the pixel plate pattern, and
wherein one end of each of the bypass reference line, the first-first bypass data line, the second-first bypass data line, and the third-first bypass data line extends to any one of a left upper end corner and a right upper end corner of the pixel plate pattern, and the other end of each of the bypass reference line, the first-first bypass data line, the second-first bypass data line, and the third-first bypass data line extends to any one of a left lower end corner and a right lower end corner of the pixel plate pattern.

21. The display device of claim 20, wherein the plurality of bypass lines further comprises:
a first-second bypass data line disposed on the pixel plate pattern and spaced apart from the first data line;
a second-second bypass data line disposed on the pixel plate pattern and spaced apart from the second data line; and
a third-second bypass data line disposed on the pixel plate pattern and spaced apart from the third data line, and
wherein one end of each of the first-second bypass data line, the second-second bypass data line, and the third-second bypass data line extends to any one of the left upper end corner and the right upper end corner of the pixel plate pattern, and the other end of each of the first-second bypass data line, the second-second bypass data line, and the third-second bypass data line extends to any one of the left lower end corner and the right lower end corner of the pixel plate pattern.

22. The display device of claim 21, wherein the plurality of lines further comprises:
a low-potential power line extending in a second direction;
a scan line extending in the second direction;
a light emission control line extending in the second direction; and
a high-potential power line extending in the second direction,
wherein the plurality of bypass lines further comprise:
a bypass low-potential power line connected to the low-potential power line on the pixel plate pattern;
a first bypass scan line connected to the scan line on the pixel plate pattern;
a first bypass light emission control line connected to the light emission control line on the pixel plate pattern; and
a bypass high-potential power line connected to the high-potential power line on the pixel plate pattern, and
wherein one end of each of the bypass low-potential power line, the first bypass scan line, the first bypass light emission control line, and the bypass high-potential power line extends to any one of the left upper end corner and the left lower end corner of the pixel plate pattern, and the other end of each of the bypass low-potential power line, the first bypass scan line, the first bypass light emission control line, and the bypass high-potential power line extends to any one of the right upper end corner and the right lower end corner of the pixel plate pattern.

23. The display device of claim 22, wherein the plurality of bypass lines further comprises:
a second bypass scan line disposed on the pixel plate pattern and spaced apart from the scan line; and
a second bypass light emission control line disposed on the pixel plate pattern and spaced apart from the light emission control line, and
wherein one end of each of the second bypass scan line and the second bypass light emission control line extends to any one of the left upper end corner and the left lower end corner of the pixel plate pattern, and the other end of each of the second bypass scan line and the second bypass light emission control line extends to any one of the right upper end corner and the right lower end corner of the pixel plate pattern.

24. The display device of claim 23, wherein on each bypass plate pattern of the plurality of bypass plate patterns, one end of each of the bypass reference line, the first-first bypass data line, the second-first bypass data line, the third-first bypass data line, the first-second bypass data line, the second-second bypass data line, and the third-second bypass data line extends to any one of a left upper end corner and a right upper end corner of the respective bypass plate pattern, and the other end of each of the bypass reference line, the first-first bypass data line, the second-first bypass data line, the third-first bypass data line, the first-second bypass data line, the second-second bypass data line, and the third-second bypass data line extends to any one of a left lower end corner and a right lower end corner of the respective bypass plate pattern, and
wherein on each bypass plate pattern of the plurality of bypass plate patterns, one end of each of the bypass low-potential power line, the first bypass scan line, the first bypass light emission control line, the bypass high-potential power line, the second bypass scan line, and the second bypass light emission control line extends to any one of the left upper end corner and the left lower end corner of the respective bypass plate pattern, and the other end of each of the bypass low-potential power line, the first bypass scan line, the first bypass light emission control line, the bypass high-potential power line, the second bypass scan line, and the second bypass light emission control line extends to any one of the right upper end corner and the right lower end corner of the respective bypass plate pattern.

25. The display device of claim 24, wherein two bypass lines, among the plurality of bypass lines, are disposed on each of the plurality of bypass plate patterns, and
wherein the display device further comprises a plurality of welding portions disposed on the plurality of bypass plate patterns and disposed between the plurality of bypass lines.

26. The display device of claim 25, wherein among the plurality of welding portions, at least one welding portion is disposed between a pair of bypass reference lines, at least one welding portion is disposed between a pair of first-first bypass data lines, at least one welding portion is disposed between a pair of second-first bypass data lines, at least one welding portion is disposed between a pair of third-first bypass data lines, at least one welding portion is disposed between the first-first bypass data line and the first-second bypass data line, at least one welding portion is disposed between the second-first bypass data line and the second-second bypass data line, at least one welding portion is disposed between the third-first bypass data line and the third-second bypass data line, at least one welding portion is disposed between a pair of bypass low-potential power lines, at least one welding portion is disposed between a pair of first bypass scan lines, at least one welding portion is disposed between a pair of first bypass light emission control lines, at least one welding portion is disposed between a pair of bypass high-potential power lines, at least one welding portion is disposed between the first bypass scan line and the second bypass scan line, and at least one welding portion is disposed between the first bypass light emission control line and the second bypass light emission control line.
